(19) United States
(12) Patent Application Publication
(10) Pub. No.: US 2026/0313997 A1
(43) Pub. Date: Oct. 8, 2026

(54) ULTRAWIDE BANDGAP SEMICONDUCTOR WITH P-TYPE CONDUCTIVITY AND METHODS OF MAKING AND USE THEREOF

(71) Applicant: OHIO STATE INNOVATION FOUNDATION, Columbus, OH (US)

(72) Inventors: Hongping ZHAO, Dublin, OH (US); Kaitian ZHANG, Columbus, OH (US)

(21) Appl. No.: 19/484,136

(22) PCT Filed: Mar. 15, 2024
(86) PCT No.: PCT/US2024/020122

§ 371 Date: Nov. 13, 2025

Related U.S. Application Data
(60) Provisional application No. 63/466,812, filed on May 16, 2023.

(51) Int. Cl. H10D 62/82; C01G 15/00; H10D 8/00; H10D 30/66

(52) U.S. Cl. CPC H10D 62/8271; C01G 15/00; C01P 2002/54; C01P 2004/03; C01P 2004/04; C01P 2006/40; H10D 8/00; H10D 30/66; H10D 30/668

(57) ABSTRACT

Disclosed herein are ultrawide bandgap semiconductors with p-type conductivity and methods of making and use thereof. Ultrawide bandgap oxide semiconductors comprise MₐGa_{b}O_{c} where M is Li or Na and where a, b, and c assume selected values.

### CROSS-REFERENCE TO RELATED APPLICATIONS

This application claims the benefit of priority to U.S. Provisional Application No. 63/466,812 filed May 16, 2023, which is hereby incorporated herein by reference in its entirety.

### STATEMENT OF GOVERNMENT SUPPORT

This invention was made with government support under FA9950-23-1-0142 awarded by the Air Force Office of Scientific Research. The government has certain rights in the invention.

### BACKGROUND

Ultrawide bandgap semiconductors with improved p-type conductivity are needed. The compositions, methods, and devices discussed herein addresses these and other needs.

### SUMMARY

In accordance with the purposes of the disclosed compositions, methods, and devices as embodied and broadly described herein, the disclosed subject matter relates to ultrawide bandgap semiconductors with p-type conductivity, and methods of making and use thereof.

For example, disclosed herein are compositions comprising ultrawide bandgap oxide semiconductor with p-type conductivity comprising MₐGa_{b}O_{c} where M is Li or Na.

In some examples, the composition comprises MₐGa_{b}O_{c} where M is Li or Na, a is from 0 to 1, b is from 0 to 5, and c is from 2 to 8, with the proviso that at least one of a or b is not 0.

In some examples, a is from 0 to 1 and b is from 0 to 1.

In some examples, a is from 0 to 1 and b is from 4 to 5.

In some examples, a is from 0 to 1 and c is 2.

In some examples, a is from 0 to 1 and c is 8.

In some examples, b is from 0 to 1 and c is 2.

In some examples, b is from 4 to 5 and c is 8.

In some examples, the composition comprises MₐGa_{b}O₈ where M is Li or Na, a is from 0 to 1, b is from 4 to 5.

In some examples, the composition comprises MₐGa_{b}O₂ where M is Li or Na, a is from 0 to 1, b is from 0 to 1, with the proviso that at least one of a or b is not 0.

In some examples, the composition comprises LiₓGa₁₋ₓO₂ or NaₓGa₁₋ₓO₂ wherein x is from 0 to 1, such as from 0 to 0.5.

In some examples, the composition comprises LiₓGa₁₋ₓO₂, wherein x is from 0 to 1, such as from 0 to 0.5. In some examples, the composition comprises β-LiₓGa₁₋ₓO₂.

In some examples, Li and Ga have an atomic ratio of from 0 to 1.

In some examples, the composition further comprises a dopant, such as a p-type dopant. In some examples, the dopant has a concentration of from 1×10¹⁵ per cubic centimeter to 1×10²¹ cm⁻³, from 1×10¹⁵ per cubic centimeter to 1×10¹⁹ cm⁻³, or from 1×10¹⁶ to 5×10¹⁷ cm⁻³.

In some examples, the composition has a mobility, such as a hole mobility, of from 0.1 to 100 cm²/Vs, such as from 1 to 10 cm²/Vs (e.g., from 2 to 5 cm²/Vs).

Also disclosed herein, are devices comprising any of the compositions disclosed herein.

In some examples, the device further comprises a substrate, wherein the composition is deposited on the substrate as a layer.

In some examples, the substrate comprises LiGaO₂, GaN on c-plane sapphire templates, on-axis c-sapphire, off-axis c-sapphire, Ga₂O₃, Si, or a combination thereof.

In some examples, the layer has a surface roughness with an RMS value of 15 nm or less, 10 nm or less, 5 nm or less, or 2.5 nm or less.

In some examples, the layer has an average thickness of from 100 to 1000 nm. In some examples, the layer has an average thickness of from 100 to 200 nm. In some examples, the layer has an average thickness of from 500 nm to 1000 nm, such as from 700 to 800 nm.

In some examples, the device comprises a vertical PN diode, a MOSFET device such as a power MOSFET or a trench MOSFET, a MESFET device, a MODFET device, a Current Aperture Vertical Electron Transistor (CAVET) device, or a combination thereof.

In some examples, the device comprises a vertical power device.

In some examples, the device comprises an optical device, an electronic device, an optoelectronic device, or a combination thereof.

In some examples, the device comprises a diode.

In some examples, the device comprises a n-Ga₂O₃/p-MₐGa_{b}O_{c}, n-AlN/p-MₐGa_{b}O_{c}, n-BN/p-MₐGa_{b}O_{c}, n-GaN/p-MₐGa_{b}O_{c}, or n-AlGaN/p-MₐGa_{b}O_{c} heterojunction. In some examples, the device comprises a n-Ga₂O₃/p-LiₐGa_{b}O_{c}, n-AlN/p-LiₐGa_{b}O_{c}, n-BN/p-LiₐGa_{b}O_{c}, n-GaN/p-LiₐGa_{b}O_{c}, or n-AlGaN/p-LiₐGa_{b}O_{c} heterojunction.

In some examples, the device comprises a n-Ga₂O₃/p-LiₐGa_{b}O₂, n-AlN/p-LiₐGa_{b}O₂, n-BN/p-LiₐGa_{b}O₂, n-GaN/p-LiₐGa_{b}O₂, or n-AlGaN/p-LiₐGa_{b}O₂ heterojunction. In some examples, the device comprises a n-Ga₂O₃/p-LiₓGa₁₋ₓO₂, n-AlN/p-LiₓGa₁₋ₓO₂, n-BN/p-LiₓGa₁₋ₓO₂, n-GaN/p-LiₓGa₁₋ₓO₂, or n-AlGaN/p-LiₓGa₁₋ₓO₂ heterojunction. In some examples, the device comprises a n-Ga₂O₃/p-LiₓGa₁₋ₓO₂ heterojunction.

In some examples, the device comprises a n-Ga₂O₃/p-LiₐGa_{b}O₈, n-AlN/p-LiₐGa_{b}O₈, n-BN/p-LiₐGa_{b}O₈, n-GaN/p-LiₐGa_{b}O₈, or n-AlGaN/p-LiₐGa_{b}O₈ heterojunction. In some examples, the device comprises a n-Ga₂O₃/p-LiGa₅O₈ heterojunction.

Also disclosed herein are methods of use of any of the compositions disclosed herein.

Also disclosed herein are methods of making any of the compositions disclosed herein. For example, the methods can comprise contacting a gallium containing precursor and a lithium or sodium containing precursor at a temperature in the presence of oxygen or an oxygen containing precursor to thereby react the gallium containing precursor, the lithium or sodium containing precursor, and the oxygen or the oxygen containing precursor to form the composition. In some examples, the methods comprise contacting the gallium containing precursor and the lithium containing precursor at a temperature in the presence of oxygen or an oxygen containing precursor to thereby react the gallium containing precursor, the lithium containing precursor, and the oxygen or the oxygen containing precursor to form the composition.

In some examples, the gallium containing precursor comprises Ga(acac)₃ ([CH₃COCH═C(O—)CH₃]₃Ga), trimethylgallium (TMGa), triethyl gallium (TEGa), or a combination thereof. In some examples, the gallium containing precursor comprises Ga(acac)₃ ([CH₃COCH═C(O—)CH₃]₃Ga).

In some examples, the sodium containing precursor comprises sodium acetoacetate (C₄H₅NaO₃), sodium tert-butoxide (NaO^{t}Bu), sodium hexamethyldisilazide (NaHMDS), 2,2,6,6-tetramethyl-3,5-heptanedionato sodium (NaTMHD), or a combination thereof.

In some examples, the lithium containing precursor comprises lithium acetoacetate (C₄H₅LiO₃), lithium tert-butoxide (LiO^{t}Bu), lithium hexamethyldisilazide (LiHMDS), 2,2,6,6-tetramethyl-3,5-heptanedionato lithium (LiTMHD), or a combination thereof. In some examples the lithium containing precursor comprises lithium acetoacetate (C₄H₅LiO₃).

In some examples, the gallium containing precursor and/or the lithium or sodium containing precursor independently comprise(s) a fluid.

In some examples, gallium containing precursor and/or the lithium or sodium containing precursor are independently provided with a carrier gas. In some examples, the carrier gas comprises argon, helium, N₂, and the like, or combinations thereof. In some examples, the carrier gas comprises argon.

In some examples, the temperature is 600° C. to 1100° C., from 600° C. to 1000° C., from 800° C. to 1000° C., or from 800° C. to 950° C.

In some examples, the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the method comprises mist-CVD.

In some examples, the method comprises depositing the composition on a substrate. In some examples, the substrate comprises LiGaO₂, GaN on c-plane sapphire templates, on-axis c-sapphire, off-axis c-sapphire, Ga₂O₃, Si, or a combination thereof.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed devices and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1A. Plan-view SEM image of LiGaO₂ sample grown on GaN-on-sapphire template at growth temperature (T_{G}) of 800° C.

FIG. 1B. Plan-view SEM image of LiGaO₂ sample grown on GaN-on-sapphire template at growth temperature (T_{G}) of 850° C.

FIG. 1C. Plan-view SEM image of LiGaO₂ sample grown on GaN-on-sapphire template at growth temperature (T_{G}) of 900° C.

FIG. 1D. Plan-view SEM image of LiGaO₂ sample grown on GaN-on-sapphire template at growth temperature (T_{G}) of 950° C.

FIG. 2A. 5 μm×5 μm AFM image of LiGaO₂ sample grown on GaN-on-sapphire template at growth temperature (T_{G}) of 800° C. The sample had an RMS ~3.45 nm.

FIG. 2B. 5 μm×5 μm AFM image of LiGaO₂ sample grown on GaN-on-sapphire template at growth temperature (T_{G}) of 850° C. The sample had an RMS ~6.43 nm.

FIG. 2C. 5 μm×5 μm AFM image of LiGaO₂ sample grown on GaN-on-sapphire template at growth temperature (T_{G}) of 900° C. The sample had an RMS ~1.60 nm.

FIG. 2D. 5 μm×5 μm AFM image of LiGaO₂ sample grown on GaN-on-sapphire template at growth temperature (T_{G}) of 950° C. The sample had an RMS ~2.46 nm.

FIG. 3. Cross-sectional SEM image of LiGaO₂ sample grown on GaN-on-sapphire template at 900° C.

FIG. 4. XRD 2θ-ω scan of LiGaO₂ sample grown on GaN-on-sapphire template at 900° C.

FIG. 5A. Plan view SEM image of LiGaO₂ sample grown on on-axis c-sapphire substrate at 850° C.

FIG. 5B. Plan view SEM image of LiGaO₂ sample grown on 6° offcut c-sapphire substrate at 850° C.

FIG. 5C. 5 μm×5 μm AFM image of LiGaO₂ sample grown on on-axis c-sapphire substrate at 850° C. Sample had an RMS ~12.1 nm.

FIG. 5D. 5 μm×5 μm AFM image of LiGaO₂ sample grown on 6° offcut c-sapphire substrate at 850° C. Sample had an RMS ~1.48 nm.

FIG. 6A. 5 μm×5 μm AFM image of LiGaO₂ sample grown on (010) Ga₂O₃ substrate at 850° C. Sample had an RMS ~7.16 nm.

FIG. 6B. 5 μm×5 μm AFM image of LiGaO₂ sample grown on (001) Ga₂O₃ substrate at 850° C. Sample had an RMS ~4.23 nm.

FIG. 7. XPS spectra of Li 1s, Ga 2p and O 1s peaks from LiGaO₂ film grown on GaN on sapphire template at 900° C.

FIG. 8A. Example design structure of p-LiGaO₂/n-β-Ga₂O₃ heterojunction PN diode.

FIG. 8B. Example design structure of LiGaO₂—Ga₂O₃ power MOSFET.

FIG. 8C. Example design structure of LiGaO₂—Ga₂O₃ trench MOSFET.

FIG. 8D. Example design structure of LiGaO₂—Ga₂O₃ CAVET.

FIG. 9A. Plan-view SEM image of LiGa₅O₈ sample grown on GaN on sapphire template at growth temperature (T_{G}) of 800° C.

FIG. 9B. Plan-view SEM image of LiGa₅O₈ sample grown on GaN on sapphire template at growth temperature (T_{G}) of 850° C.

FIG. 9C. Plan-view SEM image of LiGa₅O₈ sample grown on GaN on sapphire template at growth temperature (T_{G}) of 900° C.

FIG. 9D. Plan-view SEM image of LiGa₅O₈ sample grown on GaN on sapphire template at growth temperature (T_{G}) of 950° C.

FIG. 10A. 5 μm×5 μm AFM image of LiGa₅O₈ sample grown on GaN on sapphire template at growth temperature (T_{G}) of 800° C.

FIG. 10B. 5 μm×5 μm AFM image of LiGa₅O₈ sample grown on GaN on sapphire template at growth temperature (T_{G}) of 850° C.

FIG. 10C. 5 μm×5 μm AFM image of LiGa₅O₈ sample grown on GaN on sapphire template at growth temperature (T_{G}) of 900° C.

FIG. 10D. 5 μm×5 μm AFM image of LiGa₅O₈ sample grown on GaN on sapphire template at growth temperature (T_{G}) of 950° C.

FIG. 11A. Cross-sectional TEM image of LiGa₅O₈ sample grown on GaN on sapphire template at 900° C. The interface is marked with dash-dot lines.

FIG. 11B. Atomic resolution HAADF STEM image of LiGa₅O₈ sample grown on GaN on sapphire template at 900° C. The interface is marked with dash-dot lines.

FIG. 12. XRD 2θ-ω scan of LiGa₅O₈ sample grown on GaN on sapphire template at 900° C.

FIG. 13A. Plan view SEM image of LiGa₅O₈ sample grown on on-axis c-sapphire substrate at 850° C.

FIG. 13B. Plan view SEM image of LiGa₅O₈ sample grown on 6° offcut c-sapphire substrate at 850° C.

FIG. 13C. 5 μm×5 μm AFM image of LiGa₅O₈ sample grown on on-axis c-sapphire substrate at 850° C.

FIG. 13D. 5 μm×5 μm AFM image of LiGa₅O₈ sample grown on 6° offcut c-sapphire substrate at 850° C.

FIG. 14A. Cross-sectional TEM image of LiGa₅O₈ sample grown on on-axis c-sapphire substrate at 850° C. The interface is marked with dash-dot lines.

FIG. 14B. Atomic resolution HAADF STEM image of LiGa₅O₈ sample grown on on-axis c-sapphire substrate at 850° C. The interface is marked with dash-dot lines.

FIG. 15. XPS spectrum near the (a) Li 1s, (b) Ga 3s and (c) O 1s peaks from LiGa₅O₈ film grown on GaN on sapphire template at 900° C.

FIG. 16A. Proposed design structure of vertical PN diodes based on n⁻—Ga₂O₃ drift layer, n⁺—Ga₂O₃ substrate and p-LiGa₅O₈ layer.

FIG. 16B. Proposed design structure of LiGa₅O₈—Ga₂O₃ MOSFET.

FIG. 16C. Proposed design structure of LiGa₅O₈—Ga₂O₃ trench MOSFET.

FIG. 16D. Proposed design structure of LiGa₅O₈—Ga₂O₃ current aperture vertical electron transistor (CAVET).

### DETAILED DESCRIPTION

The compositions, methods, and devices described herein may be understood more readily by reference to the following detailed description of specific aspects of the disclosed subject matter and the Examples included therein.

Before the present compositions, methods, and devices are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Values can be expressed herein as an “average” value. “Average” generally refers to the statistical mean value.

By “substantially” is meant within 5%, e.g., within 4%, 3%, 2%, or 1%.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

References in the specification and concluding claims to parts by weight of a particular element or component in a composition denotes the weight relationship between the element or component and any other elements or components in the composition or article for which a part by weight is expressed. Thus, in a compound containing 2 parts by weight of component X and 5 parts by weight component Y, X and Y are present at a weight ratio of 2:5, and are present in such ratio regardless of whether additional components are contained in the compound.

A weight percent (wt. %) of a component, unless specifically stated to the contrary, is based on the total weight of the formulation or composition in which the component is included.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

Disclosed herein are ultrawide bandgap semiconductors with p-type conductivity and methods of making and use thereof.

For example, disclosed herein are compositions comprising ultrawide bandgap oxide semiconductor with p-type conductivity comprising MₐGa_{b}O_{c} where M is Li or Na.

In some examples, the composition comprises MₐGa_{b}O_{c} where M is Li or Na, a is from 0 to 1, b is from 0 to 5, and c is from 2 to 8, with the proviso that at least one of a or b is not 0.

For example, a can be 0 or more (e.g., 0.05 or more, 0.1 or more, 0.15 or more, 0.2 or more, 0.25 or more, 0.3 or more, 0.35 or more, 0.4 or more, 0.45 or more, 0.5 or more, 0.55 or more, 0.6 or more, 0.65 or more, 0.7 or more, 0.8 or more, 0.85 or more, or 0.9 or more). In some examples, a can be 1 or less (e.g., 0.95 or less, 0.9 or less, 0.85 or less, 0.8 or less, 0.75 or less, 0.7 or less, 0.65 or less, 0.6 or less, 0.55 or less, 0.5 or less, 0.45 or less, 0.4 or less, 0.35 or less, 0.3 or less, 0.25 or less, 0.2 or less, 0.15 or less, or 0.1 or less). The value of a can range from any of the minimum values described above to any of the maximum values described above. For example, a can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.4, from 0 to 0.3, or from 0 to 0.1).

In some examples, b is 0 or more (e.g., 0.05 or more, 0.1 or more, 0.15 or more, 0.2 or more, 0.25 or more, 0.3 or more, 0.35 or more, 0.4 or more, 0.45 or more, 0.5 or more, 0.55 or more, 0.6 or more, 0.65 or more, 0.7 or more, 0.8 or more, 0.85 or more, 0.9 or more, 1 or more, 1.1 or more, 1.2 or more, 1.3 or more, 1.4 or more, 1.5 or more, 1.6 or more, 1.7 or more, 1.8 or more, 1.9 or more, 2 or more, 2.1 or more, 2.2 or more, 2.3 or more, 2.4 or more, 2.5 or more, 2.6 or more, 2.7 or more, 2.8 or more, 2.9 or more, 3 or more, 3.1 or more, 3.2 or more, 3.3 or more, 3.4 or more, 3.5 or more, 3.6 or more, 3.7 or more, 3.8 or more, 3.9 or more, 4 or more, 4.1 or more, 4.2 or more, 4.3 or more, 4.4 or more, 4.5 or more, 4.6 or more, 4.7 or more, 4.8 or more, or 4.9 or more). In some examples, b is 5 or less (e.g., 4.9 or less, 4.8 or less, 4.7 or less, 4.6 or less, 4.5 or less, 4.4 or less, 4.3 or less, 4.2 or less, 4.1 or less, 4 or less, 3.9 or less, 3.8 or less, 3.7 or less, 3.6 or less, 3.5 or less, 3.4 or less, 3.3 or less, 3.2 or less, 3.1 or less, 3 or less, 2.9 or less, 2.8 or less, 2.7 or less, 2.6 or less, 2.5 or less, 2.4 or less, 2.3 or less, 2.1 or less, 2 or less, 1.9 or less, 1.8 or less, 1.7 or less, 1.6 or less, 1.5 or less, 1.4 or less, 1.3 or less, 1.2 or less, 1.1 or less, 1 or less, 0.95 or less, 0.9 or less, 0.85 or less, 0.8 or less, 0.75 or less, 0.7 or less, 0.65 or less, 0.6 or less, 0.55 or less, 0.5 or less, 0.45 or less, 0.4 or less, 0.35 or less, 0.3 or less, 0.25 or less, 0.2 or less, 0.15 or less, or 0.1 or less). The value of b can range from any of the minimum values described above to any of the maximum values described above. For example, b can be from 0 to 5 (e.g., from 0 to 2.5, from 2.5 to 5, from 0 to 1, from 1 to 2, from 2 to 3, from 3 to 4, from 4 to 50, from 0 to 4, from 0 to 3, from 0 to 2, from 1 to 5, from 2 to 5, from 3 to 5, from 0.1 to 4.9, from 0.5 to 4.5, or from 1 to 4).

In some examples, a can be from 0 to 1 and b can be from 0 to 1. In some examples, a can be from 0 to 1 and b can be from 4 to 5.

In some examples, c is 0 or more (e.g., 0.05 or more, 0.1 or more, 0.15 or more, 0.2 or more, 0.25 or more, 0.3 or more, 0.35 or more, 0.4 or more, 0.45 or more, 0.5 or more, 0.55 or more, 0.6 or more, 0.65 or more, 0.7 or more, 0.8 or more, 0.85 or more, 0.9 or more, 1 or more, 1.1 or more, 1.2 or more, 1.3 or more, 1.4 or more, 1.5 or more, 1.6 or more, 1.7 or more, 1.8 or more, 1.9 or more, 2 or more, 2.1 or more, 2.2 or more, 2.3 or more, 2.4 or more, 2.5 or more, 2.6 or more, 2.7 or more, 2.8 or more, 2.9 or more, 3 or more, 3.1 or more, 3.2 or more, 3.3 or more, 3.4 or more, 3.5 or more, 3.6 or more, 3.7 or more, 3.8 or more, 3.9 or more, 4 or more, 4.1 or more, 4.2 or more, 4.3 or more, 4.4 or more, 4.5 or more, 4.6 or more, 4.7 or more, 4.8 or more, 4.9 or more, 5 or more, 5.1 or more, 5.2 or more, 5.3 or more, 5.4 or more, 5.5 or more, 5.6 or more, 5.7 or more, 5.8 or more, 5.9 or more, 6 or more, 6.1 or more, 6.2 or more, 6.3 or more, 6.4 or more, 6.5 or more, 6.6 or more, 6.7 or more, 6.8 or more, 6.9 or more, 7 or more, 7.1 or more, 7.2 or more, 7.3 or more, 7.4 or more, 7.5 or more, 7.6 or more, 7.7 or more, or 7.8 or more). In some examples, c is 8 or less (e.g., 7.9 or less, 7.8 or less, 7.7 or less, 7.6 or less, 7.5 or less, 7.4 or less, 7.3 or less, 7.2 or less, 7.1 or less, 7 or less, 6.9 or less, 6.8 or less, 6.7 or less, 6.6 or less, 6.5 or less, 6.4 or less, 6.3 or less, 6.2 or less, 6.1 or less, 6 or less, 5.9 or less, 5.8 or less, 5.7 or less, 5.6 or less, 5.5 or less, 5.4 or less, 5.3 or less, 5.2 or less, 5.1 or less, 5 or less, 4.9 or less, 4.8 or less, 4.7 or less, 4.6 or less, 4.5 or less, 4.4 or less, 4.3 or less, 4.2 or less, 4.1 or less, 4 or less, 3.9 or less, 3.8 or less, 3.7 or less, 3.6 or less, 3.5 or less, 3.4 or less, 3.3 or less, 3.2 or less, 3.1 or less, 3 or less, 2.9 or less, 2.8 or less, 2.7 or less, 2.6 or less, 2.5 or less, 2.4 or less, 2.3 or less, 2.1 or less, 2 or less, 1.9 or less, 1.8 or less, 1.7 or less, 1.6 or less, 1.5 or less, 1.4 or less, 1.3 or less, 1.2 or less, 1.1 or less, 1 or less, 0.95 or less, 0.9 or less, 0.85 or less, 0.8 or less, 0.75 or less, 0.7 or less, 0.65 or less, 0.6 or less, 0.55 or less, 0.5 or less, 0.45 or less, 0.4 or less, 0.35 or less, 0.3 or less, 0.25 or less, 0.2 or less, 0.15 or less, or 0.1 or less). The value of c can range from any of the minimum values described above to any of the maximum values described above. For example, c can be from 0 to 8 (e.g., from 0 to 4, from 4 to 8, from 0 to 2, from 2 to 4, from 4 to 6, from 6 to 8, from 0 to 6, from 0 to 4, from 2 to 8, from 4 to 8, from 1 to 7, or from 2 to 6). In some examples, c is 2. In some examples, c is 8.

In some examples, a is 0 to 1 and c is 2. In some examples, a is 0 to 1 and c is 8.

In some examples, b is 0 to 1 and c is 2. In some examples, b is 4 to 5 and c is 8.

In some examples, a is from 0 to 1, b is from 0 to 1, and c is 2. In some examples, a is from 0 to 1, b is 4 to 5, and c is 8.

For example, disclosed herein are compositions comprising MₐGa_{b}O₈ where M is Li or Na, a is from 0 to 1, b is from 4 to 5.

In some examples, the composition comprises MₐGa_{b}O₂ where M is Li or Na, a is from 0 to 1, b is from 0 to 1, with the proviso that at least one of a or b is not 0.

For example, disclosed herein are compositions comprising ultrawide bandgap oxide semiconductor with p-type conductivity comprising LiₓGa₁₋ₓO₂ or NaₓGa₁₋ₓO₂, wherein x is from 0 to 1. In some examples, the composition comprises NaₓGa₁₋ₓO₂. In some examples, the composition comprises LiₓGa₁₋ₓO₂, wherein x is from 0 to 1. In some examples, the composition comprises β-LiₓGa₁₋ₓO₂.

For example, x can be 0 or more (e.g., 0.05 or more, 0.1 or more, 0.15 or more, 0.2 or more, 0.25 or more, 0.3 or more, 0.35 or more, 0.4 or more, 0.45 or more, 0.5 or more, 0.55 or more, 0.6 or more, 0.65 or more, 0.7 or more, 0.8 or more, 0.85 or more, or 0.9 or more). In some examples, x can be 1 or less (e.g., 0.95 or less, 0.9 or less, 0.85 or less, 0.8 or less, 0.75 or less, 0.7 or less, 0.65 or less, 0.6 or less, 0.55 or less, 0.5 or less, 0.45 or less, 0.4 or less, 0.35 or less, 0.3 or less, 0.25 or less, 0.2 or less, 0.15 or less, or 0.1 or less). The value of x can range from any of the minimum values described above to any of the maximum values described above. For example, x can be from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.4, from 0 to 0.3, or from 0 to 0.1). In some examples, the composition comprises an ultrawide bandgap oxide semiconductor with p-type conductivity comprising LiₓGa₁₋ₓO₂ (e.g., β-LiₓGa₁₋ₓO₂), wherein x is from 0 to 0.5.

In some examples, Li and Ga have an atomic ratio of from 0 to 1. For example, Li and Ga can have an atomic ratio of 0 or more (e.g., 0.05 or more, 0.1 or more, 0.15 or more, 0.2 or more, 0.25 or more, 0.3 or more, 0.35 or more, 0.4 or more, 0.45 or more, 0.5 or more, 0.55 or more, 0.6 or more, 0.65 or more, 0.7 or more, 0.8 or more, 0.85 or more, or 0.9 or more). In some examples, Li and Ga can have an atomic ratio of 1 or less (e.g., 0.95 or less, 0.9 or less, 0.85 or less, 0.8 or less, 0.75 or less, 0.7 or less, 0.65 or less, 0.6 or less, 0.55 or less, 0.5 or less, 0.45 or less, 0.4 or less, 0.35 or less, 0.3 or less, 0.25 or less, 0.2 or less, 0.15 or less, or 0.1 or less). The atomic ratio of Li and Ga can range from any of the minimum values described above to any of the maximum values described above. For example, Li and Ga can have an atomic ratio of from 0 to 1 (e.g., from 0 to 0.5, from 0.5 to 1, from 0 to 0.2, from 0.2 to 0.4, from 0.4 to 0.6, from 0.6 to 0.8, from 0.8 to 1, from 0 to 0.9, from 0 to 0.8, from 0 to 0.7, from 0 to 0.6, from 0 to 0.4, from 0 to 0.3, from 0 to 0.1, from 0.1 to 1, from 0.2 to 1, from 0.3 to 1, from 0.4 to 1, from 0.6 to 1, from 0.7 to 1, from 0.9 to 1, from 0.1 to 0.9, or from 0.2 to 0.8). In some examples, Li and Ga have an atomic ratio of from 0.1 to 0.3.

In some examples, the composition further comprises a dopant, such as a p-type dopant. In some examples, the dopant has a concentration of 1×10¹⁵ per cubic centimeter (cm⁻³) or more (e.g., 5×10¹⁵ cm⁻³ or more, 1×10¹⁶ cm⁻³ or more, 5×10¹⁶ cm⁻³ or more, 1×10¹⁷ cm⁻³ or more, 5×10¹⁷ cm⁻³ or more, 1×10¹⁸ cm⁻³ or more, 5×10¹⁸ cm⁻³ or more, 1×10¹⁹ cm⁻³ or more, 5×10¹⁹ cm⁻³ or more, 1×10²⁰ cm⁻³ or more, or 5×10²⁰ cm⁻³ or more). In some examples, the dopant has a concentration of 1×10²¹ cm⁻³ or less (e.g., 5×10²⁰ cm⁻³ or less, 1×10²⁰ cm⁻³ or less, 5×10¹⁹ cm⁻³ or less, 1×10¹⁹ cm⁻³ or less, 5×10¹⁸ cm⁻³ or less, 1×10¹⁸ cm⁻³ or less, 5×10¹⁷ cm⁻³ or less, 1×10¹⁷ cm⁻³ or less, 5×10¹⁶ cm⁻³ or less, 1×10¹⁵ cm⁻³ or less, or 5×10¹⁵ cm-3 or less). The concentration of the dopant can range from any of the minimum values described above to any of the maximum values described above. For example, the dopant can have a concentration of from 1×10¹⁵ per cubic centimeter (cm⁻³) to 1×10²¹ cm⁻³ (e.g., from 1×10¹⁵ to 1×10¹⁷ cm⁻³, from 1×10¹⁷ to 1×10²¹ cm⁻³, from 1×10¹⁵ to 1×10¹⁷ cm⁻³, from 1×10¹⁷ to 1×10¹⁹ cm⁻³, from 1×10¹⁹ cm⁻³ to 1×10²¹ cm⁻³, from 1×10¹⁵ to 1×10¹⁶ cm⁻³, from 1×10¹⁶ to 1×10¹⁷ cm⁻³, from 1×10¹⁷ to 1×10¹⁸ cm⁻³, from 1×10¹⁸ to 1×10¹⁹ cm⁻³, from 1×10¹⁹ to 1×10²⁰ cm⁻³, from 1×10²⁰ to 1×10²¹ cm⁻³, from 1×10¹⁵ to 1×10²⁰ cm⁻³, from 1×10¹⁵ to 1×10¹⁹ cm⁻³, from 1×10¹⁵ to 1×10¹⁸ cm⁻³, from 1×10¹⁶ to 1×10²¹ cm⁻³, from 1×10¹⁷ to 1×10²¹ cm⁻³, from 1×10¹⁸ to 1×10²¹ cm⁻³, from 1×10¹⁶ to 1×10²⁰ cm⁻³, from 1×10¹⁶ to 1×10¹⁹ cm⁻³, from 1×10¹⁶ to 1×10¹⁸ cm⁻³, or from 1×10¹⁶ to 5×10¹⁷ cm⁻³). In some examples, the dopant has a concentration of from 1×10¹⁵ per cubic centimeter (cm⁻³) to 1×10¹⁹ cm⁻³. In some examples, the dopant has a concentration of from 1×10¹⁶ to 5×10¹⁷ cm⁻³.

In some examples, the composition has a mobility, such as a hole mobility, of 0.1 cm²/Vs or more (e.g., 0.25 cm²/Vs or more, 0.5 cm²/Vs or more, 0.75 cm²/Vs or more, 1 cm²/Vs or more, 1.5 cm²/Vs or more, 2 cm²/Vs or more, 2.5 cm²/Vs or more, 3 cm²/Vs or more, 3.5 cm²/Vs or more, 4 cm²/Vs or more, 4.5 cm²/Vs or more, 5 cm²/Vs or more, 5.5 cm²/Vs or more, 6 cm²/Vs or more, 6.5 cm²/Vs or more, 7 cm²/Vs or more, 7.5 cm²/Vs or more, 8 cm²/Vs or more, 8.5 cm²/Vs or more, 9 cm²/Vs or more, 10 cm²/Vs or more, 11 cm²/Vs or more, 12 cm²/Vs or more, 13 cm²/Vs or more, 14 cm²/Vs or more, 15 cm²/Vs or more, 20 cm²/Vs or more, 25 cm²/Vs or more, 30 cm²/Vs or more, 35 cm²/Vs or more, 40 cm²/Vs or more, 45 cm²/Vs or more, 50 cm²/Vs or more, 55 cm²/Vs or more, 60 cm²/Vs or more, 65 cm²/Vs or more, 70 cm²/Vs or more, 75 cm²/Vs or more, 80 cm²/Vs or more, 85 cm²/Vs or more, or 90 cm²/Vs or more). In some examples, the composition has a mobility, such as a hole mobility, of 100 cm²/Vs or less (e.g., 95 cm²/Vs or less, 90 cm²/Vs or less, 85 cm²/Vs or less, 80 cm²/Vs or less, 75 cm²/Vs or less, 70 cm²/Vs or less, 65 cm²/Vs or less, 60 cm²/Vs or less, 55 cm²/Vs or less, 50 cm²/Vs or less, 45 cm²/Vs or less, 40 cm²/Vs or less, 35 cm²/Vs or less, 30 cm²/Vs or less, 25 cm²/Vs or less, 20 cm²/Vs or less, 15 cm²/Vs or less, 14 cm²/Vs or less, 13 cm²/Vs or less, 12 cm²/Vs or less, 11 cm²/Vs or less, 10 cm²/Vs or less, 9.5 cm²/Vs or less, 9 cm²/Vs or less, 8.5 cm²/Vs or less, 8 cm²/Vs or less, 7.5 cm²/Vs or less, 7 cm²/Vs or less, 6.5 cm²/Vs or less, 6 cm²/Vs or less, 5.5 cm²/Vs or less, 5 cm²/Vs or less, 4.5 cm²/Vs or less, 4 cm²/Vs or less, 3.5 cm²/Vs or less, 3 cm²/Vs or less, 2.5 cm²/Vs or less, 2 cm²/Vs or less, 1.5 cm²/Vs or less, 1 cm²/Vs or less, 0.75 cm²/Vs or less, or 0.5 cm²/Vs or less). The mobility (e.g., the hole mobility) of the composition can range from any of the minimum values described above to any of the maximum values described above. For example, the composition can have a mobility, such as a hole mobility, of from 0.1 to 100 cm²/Vs (e.g., from 0.1 to 50 cm²/Vs, from 50 to 100 cm²/Vs, from 0.1 to 20 cm²/Vs, from 20 to 40 cm²/Vs, from 40 to 60 cm²/Vs, from 60 to 80 cm²/Vs, from 80 to 100 cm²/Vs, from 0.1 to 80 cm²/Vs, from 0.1 to 60 cm²/Vs, from 0.1 to 20 cm²/Vs, from 0.1 to 10 cm²/Vs, from 0.1 to 5 cm²/Vs, from 0.5 to 100 cm²/Vs, from 1 to 100 cm²/Vs, from 5 to 100 cm²/Vs, from 10 to 100 cm²/Vs, from 20 to 100 cm²/Vs, from 40 to 100 cm²/Vs, form 60 to 100 cm²/Vs, from 0.25 to 90 cm²/Vs, from 0.5 to 75 cm²/Vs, from 0.75 to 50 cm²/Vs, from 1 to 25 cm²/Vs, or from 1 to 10 cm²/Vs). In some examples, the composition can have a mobility, such as a hole mobility, of from 1 to 10 cm²/Vs (e.g., from 1 to 5 cm²/Vs, from 5 to 10 cm²/Vs, from 1 to 4 cm²/Vs, from 4 to 7 cm²/Vs, from 7 to 10 cm²/Vs, from 1 to 8 cm²/Vs, from 1 to 6 cm²/Vs, from 1 to 3 cm²/Vs, from 2 to 10 cm²/Vs, from 4 to 10 cm²/Vs, from 6 to 10 cm²/Vs, from 8 to 10 cm²/Vs, from 1.5 to 9.5 cm²/Vs, or from 2 to 5 cm²/Vs).

Also disclosed herein are devices comprising any of the compositions disclosed herein.

In some examples, the device further comprises a substrate, wherein the composition is deposited on the substrate as a layer. The substrate can comprise any suitable substate. For example, the substrate can comprise LiGaO₂, GaN on c-plane sapphire templates, on-axis c-sapphire, off-axis c-sapphire, Ga₂O₃, Si, or a combination thereof.

In some examples, the layer has a surface roughness with a RMS value of 15 nm or less (e.g., 14.5 nm or less, 14 nm or less, 13.5 nm or less, 13 nm or less, 12.5 nm or less, 12 nm or less, 11.5 nm or less, 11 nm or less, 10.5 nm or less, 10 nm or less, 9.5 nm or less, 9 nm or less, 8.5 nm or less, 8 nm or less, 7.5 nm or less, 7 nm or less, 6.5 nm or less, 6 nm or less, 5.5 nm or less, 5 nm or less, 4.5 nm or less, 4 nm or less, 3.5 nm or less, 3 nm or less, 2.5 nm or less, 2 nm or less, 1.5 nm or less, 1 nm or less, or 0.5 nm or less). In some examples, the layer has a surface roughness with an RMS value of 10 nm or less. In some examples, the layer has a surface roughness with an RMS value of 5 nm or less. In some examples, the layer has a surface roughness with an RMS value of 2.5 nm or less.

In some examples, the layer has an average thickness of 100 nanometers (nm) or more (e.g., 125 nm or more, 150 nm or more, 175 nm or more, 200 nm or more, 225 nm or more, 250 nm or more, 275 nm or more, 300 nm or more, 325 nm or more, 350 nm or more, 375 nm or more, 400 nm or more, 425 nm or more, 450 nm or more, 475 nm or more, 500 nm or more, 525 nm or more, 550 nm or more, 575 nm or more, 600 nm or more, 625 nm or more, 650 nm or more, 675 nm or more, 700 nm or more, 725 nm or more, 750 nm or more, 775 nm or more, 800 nm or more, 825 nm or more, 850 nm or more, 875 nm or more, 900 nm or more, 925 nm or more, or 950 nm or more). In some examples, the layer has an average thickness of 1000 nm or less (e.g., 975 nm or less, 950 nm or less, 925 nm or less, 900 nm or less, 875 nm or less, 850 nm or less, 825 nm or less, 800 nm or less, 775 nm or less, 750 nm or less, 725 nm or less, 700 nm or less, 675 nm or less, 650 nm or less, 625 nm or less, 600 nm or less, 575 nm or less, 550 nm or less, 525 nm or less, 500 nm or less, 475 nm or less, 450 nm or less, 425 nm or less, 400 nm or less, 375 nm or less, 350 nm or less, 325 nm or less, 300 nm or less, 275 nm or less, 250 nm or less, 225 nm or less, 200 nm or less, 175 nm or less, or 150 nm or less). The average thickness of the layer can range from any of the minimum values described above to any of the maximum values described above. For example, the layer can have an average thickness of from 100 to 1000 nm (e.g., from 100 to 500 nm, from 500 to 1000 nm, from 100 to 250 nm, from 250 nm to 500 nm, from 500 to 750 nm, from 750 to 1000 nm, from 100 to 200 nm, from 200 to 300 nm, from 300 to 400 nm, from 400 to 500 nm, from 500 to 600 nm, from 600 to 700 nm, from 700 to 800 nm, from 800 to 900 nm, from 900 to 1000 nm, from 100 to 900 nm, from 100 to 800 nm, from 100 to 700 nm, from 100 to 600 nm, from 100 to 400 nm, from 100 to 300 nm, from 200 to 1000 nm, from 300 to 1000 nm, from 400 to 1000 nm, from 600 to 1000 nm, from 700 to 1000 nm, from 800 to 1000 nm, from 150 to 950 nm, from 200 to 900 nm, from 500 to 900 nm, from 500 to 800 nm, from 500 to 700 nm, from 550 to 1000 nm, from 550 to 950 nm, from 600 to 900 nm, from 700 to 800 nm, or from 725 to 775 nm). In some examples, the layer can have an average thickness of from 100 to 200 nm. In some examples, the layer can have an average thickness of from 700 to 800 nm.

The device can comprise any suitable device. In some examples, the device comprises a vertical PN diode, a MOSFET device such as a power MOSFET or a trench MOSFET, a MESFET device, a MODFET device, a Current Aperture Vertical Electron Transistor (CAVET) device, or a combination thereof. In some examples, the device comprises a vertical power device. In some examples, the device comprises an optical device, an electronic device, an optoelectronic device, or a combination thereof. In some examples, the device comprises a diode.

In some examples, the device comprises a n-Ga₂O₃/p-MₐGa_{b}O_{c}, n-AlN/p-MₐGa_{b}O_{c}, n-BN/p-MₐGa_{b}O_{c}, n-GaN/p-MₐGa_{b}O_{c}, or n-AlGaN/p-MₐGa_{b}O_{c} heterojunction.

In some examples, the device comprises a n-Ga₂O₃/p-LiₐGa_{b}O_{c}, n-AlN/p-LiₐGa_{b}O_{c}, n-BN/p-LiₐGa_{b}O_{c}, n-GaN/p-LiₐGa_{b}O_{c}, or n-AlGaN/p-LiₐGa_{b}O_{c} heterojunction.

In some examples, the device comprises a n-Ga₂O₃/p-LiₐGa_{b}O₂, n-AlN/p-LiₐGa_{b}O₂, n-BN/p-LiₐGa_{b}O₂, n-GaN/p-LiₐGa_{b}O₂, or n-AlGaN/p-LiₐGa_{b}O₂ heterojunction.

In some examples, the device comprises a n-Ga₂O₃/p-LiₓGa₁₋ₓO₂, n-AlN/p-LiₓGa₁₋ₓO₂, n-BN/p-LiₓGa₁₋ₓO₂, n-GaN/p-LiₓGa₁₋ₓO₂, or n-AlGaN/p-LiₓGa₁₋ₓO₂ heterojunction.

In some examples, the device comprises a n-Ga₂O₃/p-LiₓGa₁₋ₓO₂ heterojunction.

In some examples, the device comprises a n-Ga₂O₃/p-LiₐGa_{b}O₂, n-AlN/p-LiₐGa_{b}O₈, n-BN/p-LiₐGa_{b}O₈, n-GaN/p-LiₐGa_{b}O₈, or n-AlGaN/p-LiₐGa_{b}O₈ heterojunction.

In some examples, the device comprises a n-Ga₂O₃/p-LiGa₅O₈ heterojunction.

Also disclosed herein are methods of use of any of the compositions disclosed herein.

Also disclosed herein are methods of making any of the compositions or devices disclosed herein. In some examples, the methods comprising contacting a gallium containing precursor and a lithium or sodium containing precursor at a temperature in the presence of oxygen or an oxygen containing precursor to thereby react the gallium containing precursor, the lithium or sodium containing precursor, and the oxygen or the oxygen containing precursor to form the composition. In some examples, the methods comprising contacting a gallium containing precursor and a lithium containing precursor at a temperature in the presence of oxygen or an oxygen containing precursor to thereby react the gallium containing precursor, the lithium containing precursor, and the oxygen or the oxygen containing precursor to form the composition.

In some examples, the gallium containing precursor comprises Ga(acac)₃ ([CH₃COCH═C(O—)CH₃]₃Ga), trimethylgallium (TMGa), triethyl gallium (TEGa), or a combination thereof. In some examples, the gallium containing precursor comprises Ga(acac)₃ ([CH₃COCH═C(O—)CH₃]₃Ga).

In some examples, the sodium containing precursor comprises sodium acetoacetate (C₄H₅NaO₃), sodium tert-butoxide (NaO^{t}Bu), sodium hexamethyldisilazide (NaHMDS), 2,2,6,6-tetramethyl-3,5-heptanedionato sodium (NaTMHD), or a combination thereof.

In some examples, the lithium containing precursor comprises lithium acetoacetate (C₄H₅LiO₃), lithium tert-butoxide (LiO^{t}Bu), lithium hexamethyldisilazide (LiHMDS), 2,2,6,6-tetramethyl-3,5-heptanedionato lithium (LiTMHD), or a combination thereof. In some examples, the lithium containing precursor comprises lithium acetoacetate (C₄H₅LiO₃).

In some examples, the gallium containing precursor and/or the lithium or sodium containing precursor independently comprise(s) a fluid.

In some examples, the gallium containing precursor and/or the lithium or sodium containing precursor are independently provided with a carrier gas. In some examples, the carrier gas comprises argon, helium, N₂, and the like, or combinations thereof. In some examples, the carrier gas comprises argon.

In some examples, the temperature is 600° C. or more (e.g., 625° C. or more, 650° C. or more, 675° C. or more, 700° C. or more, 725° C. or more, 750° C. or more, 775° C. or more, 800° C. or more, 825° C. or more, 850° C. or more, 875° C. or more, 900° C. or more, 925° C. or more, 950° C. or more, 975° C. or more, 1000° C. or more, 1025° C. or more, or 1050° C. or more). In some examples, the temperature is 1100° C. or less (e.g., 1075° C. or less, 1050° C. or less, 1025° C. or less, 1000° C. or less, 975° C. or less, 950° C. or less, 925° C. or less, 900° C. or less, 875° C. or less, 850° C. or less, 825° C. or less, 800° C. or less, 775° C. or less, 750° C. or less, 725° C. or less, 700° C. or less, 675° C. or less, or 650° C. or less). The temperature can range from any of the minimum values described above to any of the maximum values described above. For example, the temperature can be from 600° C. to 1100° C. (e.g., from 600° C. to 850° C., from 850° C. to 1100° C., from 600° C. to 700° C., from 700° C. to 800° C., from 800° C. to 900° C., from 900° C. to 1000° C., from 1000° C. to 1100° C., from 600° C. to 1000° C., from 600° C. to 900° C., from 600° C. to 800° C., from 700° C. to 1100° C., from 800° C. to 1100° C., from 900° C. to 1100° C., from 650° C. to 1050° C., from 700° C. to 1000° C., from 800° C. to 1000° C., from 650° C. to 950° C., or from 800° C. to 950° C.). In some examples, the temperature can be from 600° C. to 1000° C., such as from 800° C. to 1000° C.

The method can, for example, comprise metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof. In some examples, the method comprises mist-CVD.

In some examples, the method comprises depositing the composition on a substrate. Examples of substrates include, but are not limited to, LiGaO₂, GaN on c-plane sapphire templates, on-axis c-sapphire, off-axis c-sapphire, Ga₂O₃, or a combination thereof.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the devices and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Ultrawide Bandgap Oxide Semiconductor LiGaO₂ with p-Type Conductivity for Power Device Applications

Beta phase gallium oxide (β-Ga₂O₃) with an ultrawide bandgap (UWBG) of ~4.8 eV has emerged as a promising semiconductor candidate for power electronic devices. Its predicted high critical field strength (~8 MV/cm) and the availability of scalable high quality Ga₂O₃ substrates synthesized from melt present Ga₂O₃ as a promising semiconductor for power electronic devices with high power density. While Ga₂O₃ stands out as a promising UWBG semiconductor material for next generation high power and high frequency electronic and optoelectronic applications, there exist certain limitations of the material that need to be addressed in order to fully maximize its potential. The lack of p-type conductivity could be a major setback for Ga₂O₃ device design. It is theoretically calculated that all major acceptor candidates for β-Ga₂O₃ act as deep acceptors (Lyons J L. Semiconductor science and technology, 2018, 33(5), 05LT02; Neal A T et al. Applied Physics Letters, 2018, 113(6), 062101), indicating a very low activation efficiency and a trap-like behavior of the acceptors. Additionally, it is also theoretically predicted that, the holes in many oxides (Ga₂O₃, In₂O₃, SnO₂, MgO) prefer the localized, self-trapped form of polarons around O-site due to the characteristic lattice distortion (Varley J B et al. Physical Review B, 2012, 85(8), 081109). Even if there are activated holes, the conductivity of such holes will be extremely low, prohibiting the p-type conductivity in such materials.

One approach to address the issue of the lack of p-type Ga₂O₃ is to form hetero pn junction using alternative p-type materials. In recent developments, p-type nickel oxide (NiO, with a bandgap of 3.4-4 eV) has been employed to create p-n junction diodes with β-Ga₂O₃ (Kokubun Y et al. Appl. Phys. Express, 2016, 9(9), 091101). NiO/Ga₂O₃ p-n diodes have attained multi-kilovolt breakdown voltage (BV) and low differential specific on-resistance (R_{ON,SP}) (Lu X et al. IEEE Electron Device Lett. 2020, 41(3), 449-452; Wang Y et al. IEEE Trans. Power Electron. 2022, 37(4), 3743-3746; Wang B et al. IEEE Electron Device Lett. 2023, 44(2), 221-224). However, the performance of these devices is limited by the relatively small bandgap of NiO.

LiGaO₂ with an optical gap larger than 5.3 eV has been considered as a transparent ceramic material for piezoelectric (Boonchun A et al. Phys. Rev. B, 2010, 81(23), 235214; Gupta S N et al. J. Appl. Phys. 1976, 47(3), 858-860; Nanamatsu S et al. Jpn. J. Appl. Phys. 1972, 11(6), 816) and nonlinear optical applications (Knoll P et al. Phys. Rev. B, 1984, 29(4), 2221-2226; Rashkeev S N et al. JOSA B, 1999, 16(12), 2217-2222) in the past. LiGaO₂ has been grown in bulk single-crystal form (Ishii T et al. J. Cryst. Growth, 1998, 186 (3), 409-419; Marezio M. Acta Crystallogr. 1965, 18(3), 481-484), which was motivated to be used as a closely-lattice matched substrate for GaN epitaxy (Christensen A et al. IEEE Trans. Electron Devices, 2005, 52(8), 1683-1688; Doolittle W A et al. Solid-State Electron. 2000, 44(2), 229-238; Sakurada K et a. Appl. Phys. Lett. 2007, 90(21), 211913; Chen C et al. J. Cryst. Growth 2014, 402, 325-329). LiGaO₂ can be viewed as a I-III-VI₂ analog of the II-VI material ZnO with a wurtzite-based crystal structure, comprising an ordered arrangement of the Li and Ga atoms on the cation sublattice of the wurtzite. In particular, it has the Pna2₁ space group as the ground state (β-LiGaO₂). Mixed alloy systems of ZnO and LiGaO₂ and ZnO/LiGaO₂ heterojunctions have also been studied (Ohkubo I et al. J. Appl. Phys. 2002, 92(9), 5587-5589; Omata T et al. J. Appl. Phys. 2008, 103(8), 083706; Omata T et al. Jpn. J. Appl. Phys. 2011, 50(3R), 031102). From the first principles calculations, it is possible that LiGaO₂ can be n-type doped with Si or Ge, which would make it promising for ultrawide-gap semiconductor applications (Boonchun A et al. J. Appl. Phys. 2019, 126(15), 155703; Boonchun A et al. Oxide-Based Mater. Devices II, SPIE, 2011, pp. 129-134; Dabsamut K et al. J. Phys. Appl. Phys. 2020, 53(27), 274002; Skachkov D et al. J. Phys. Appl. Phys. 2020, 53(17), 17LT01). However, doping studies in LiGaO₂ are still lacking.

Herein, an UWBG semiconductor Li-poor or Li-rich LiGaO₂ with p-type conductivity is introduced. As an example, the Li-poor or Li-rich LiGaO₂ can be obtained by mist chemical vapor deposition (mist-CVD) technique. Unintentionally doped Li-poor or Li-rich LiGaO₂ thin films are deposited using a custom-designed mist-CVD chamber on various substrates, including LiGaO₂, GaN on c-plane sapphire templates, on-axis c-sapphire, off-axis c-sapphire, and Ga₂O₃ substrates. The source solutions are prepared by directly dissolving gallium acetylacetonate (Ga(acac)₃, [CH₃COCH═C(O—)CH₃]₃Ga, 99.99%) and lithium acetoacetate (C₄H₅LiO₃, 97%) in deionized (DI) water. The Ga/Li molar ratio can be tuned to be <1, =1, or >1. The solutions are stirred at room temperature and ultrasonically atomized into spray or mist particles with an ultrasonic generator. The atomized particles are then delivered into a growth chamber using Argon (Ar) as the carrier gas. Growth substrates are loaded in the growth chamber and the growth temperature can be tuned widely between 60° and 1100° C., such as 600-1000° C.

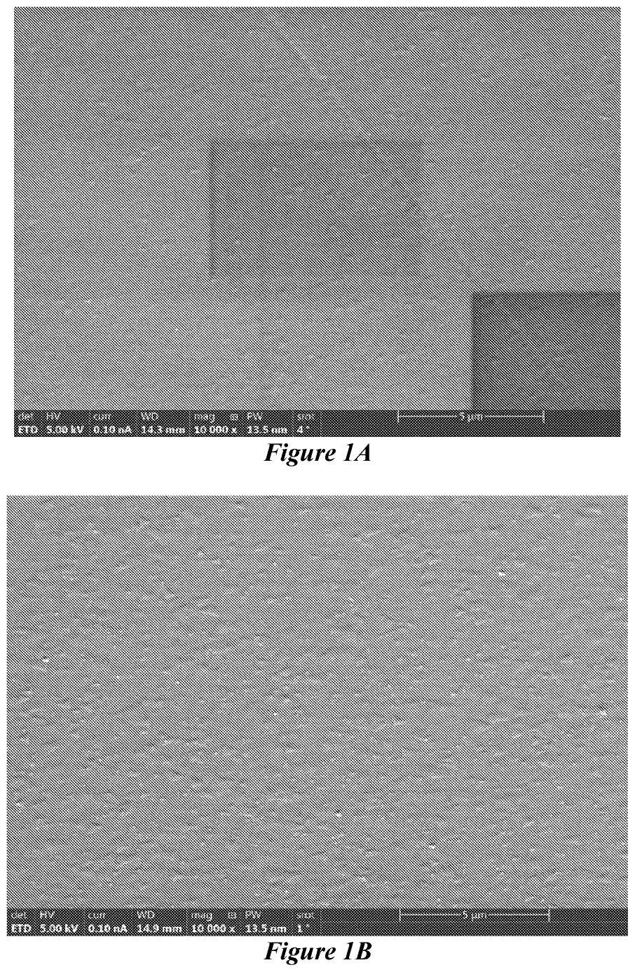

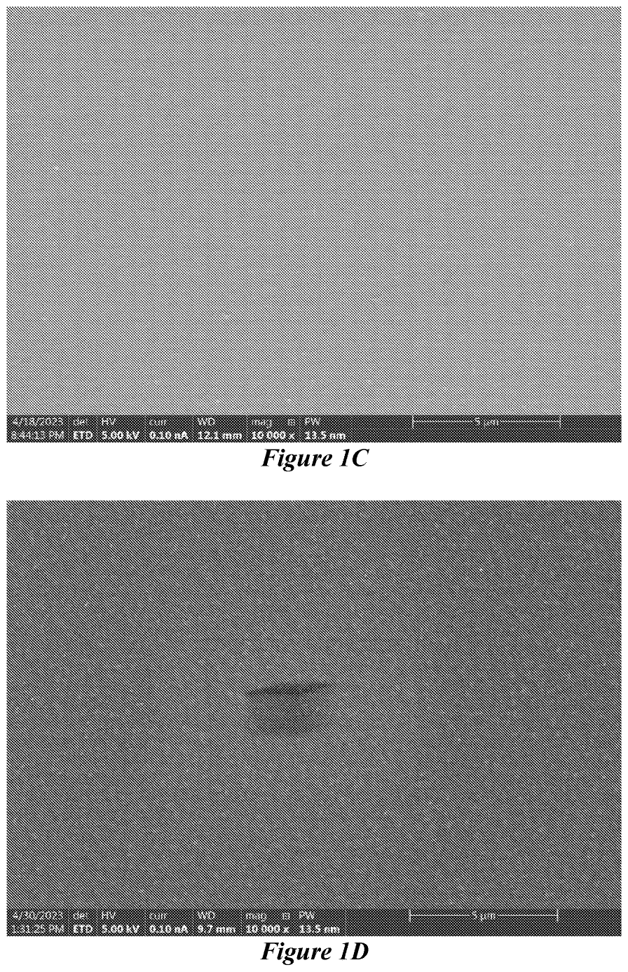

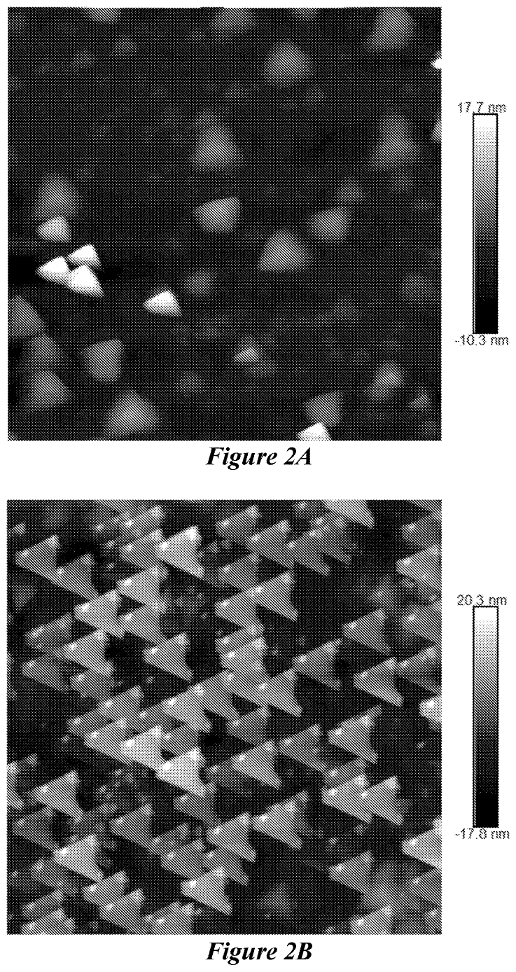

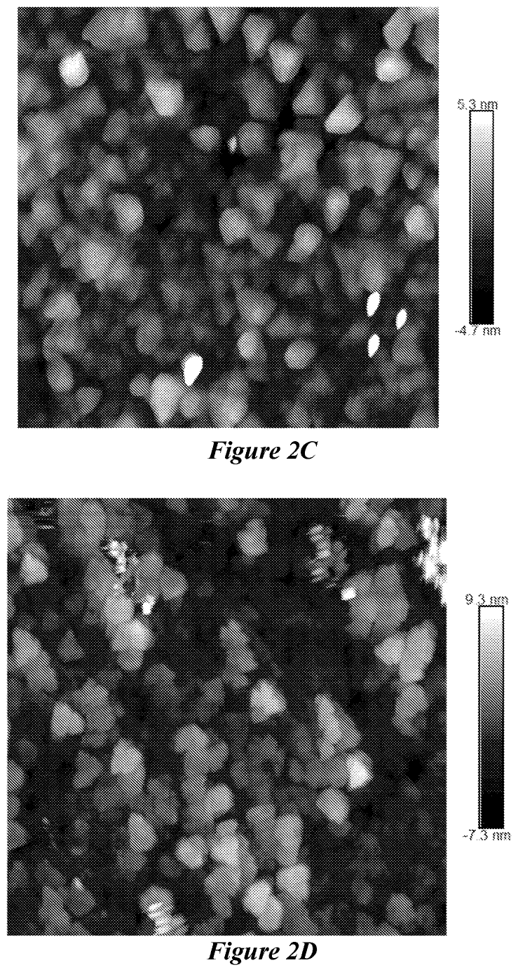

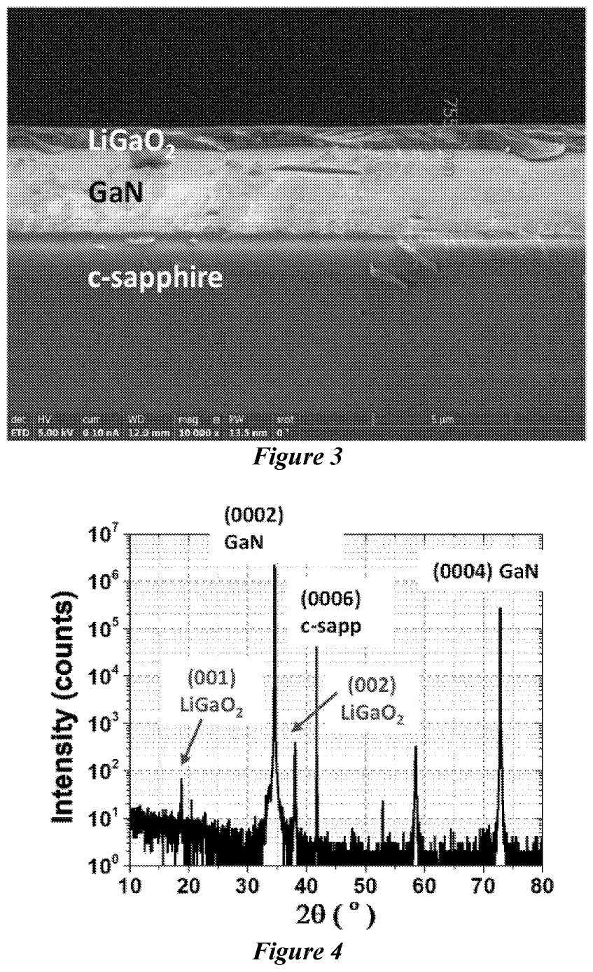

FIG. 1A-FIG. 1D shows the surface morphology of the LiGaO₂ samples grown on GaN-on-sapphire templates at different growth temperatures. The relatively small lattice mismatch (~2%) between GaN and LiGaO₂ allows the growth of the film with high quality. It is confirmed from the corresponding AFM images shown in FIG. 2A-FIG. 2D that at the growth temperature of 900° C., the surface has a low surface roughness with RMS value of 1.6 nm. The thickness of the as-grown film at 900° C. is estimated by cross-sectional SEM image to be around 750 nm, as is shown in FIG. 3. The growth time is 30 minutes. A sharp interface between the grown film and GaN template can be observed. FIG. 4 shows the XRD spectrum of the same sample. The XRD peaks at ~34.55°, 41.68°, and 72.86° are attributed to the GaN and sapphire peaks from the substrate template, while clear LiGaO₂ (001) and (002) peaks at ~18.74° and 38.01° can be observed.

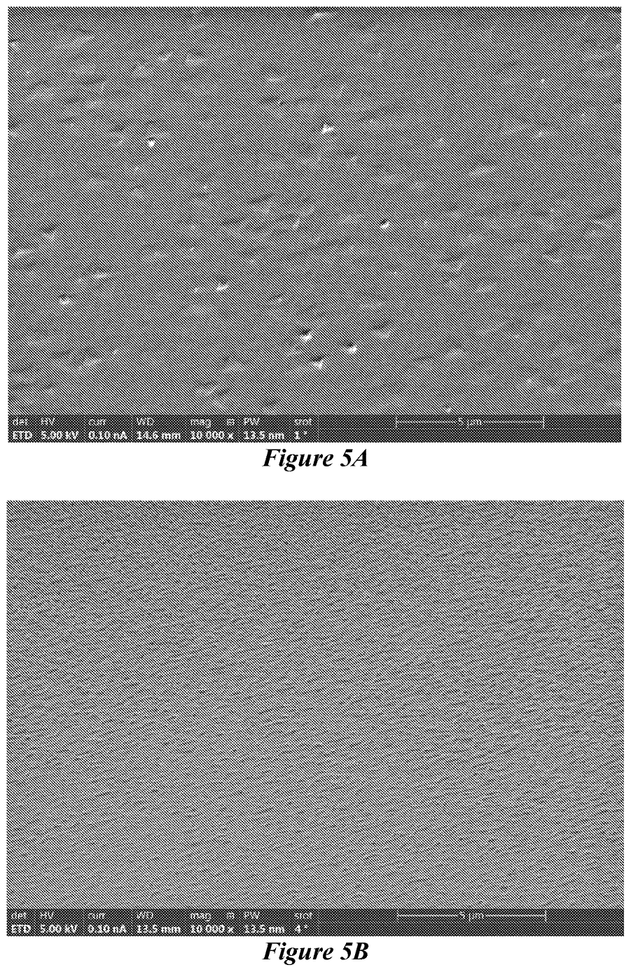

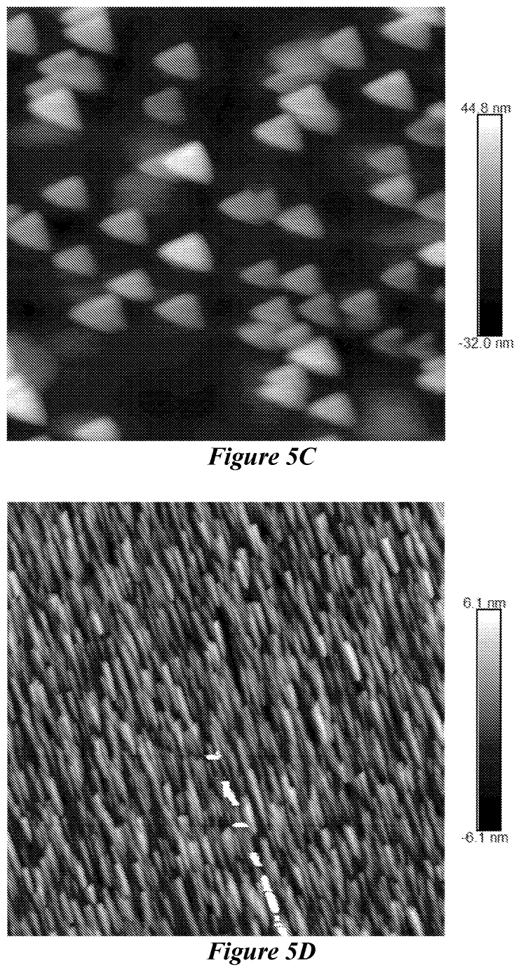

FIG. 5A-FIG. 5D shows the plan-view SEM images of the LiGaO₂ samples grown at 850° C. on on-axis and 6°-offcut c-plane sapphire substrates, and the corresponding AFM images. The relatively rougher surface of the LiGaO₂ sample grown on the on-axis c-sapphire substrate is attributed to the larger lattice mismatch between LiGaO₂ and sapphire (~5-12% depending on the growth direction). However, it is worth noting that with the use of offcut sapphire substrates, the surface morphology shows much smoother surface with RMS value of 1.48 nm. Room temperature van der Pauw Hall measurements of the LiGaO₂ films grown on c-sapphire substrate indicate robust p-type conductivity, with room temperature doping concentration of low-mid 10¹⁷ cm⁻³ and mobility of 2-5 cm²/Vs.

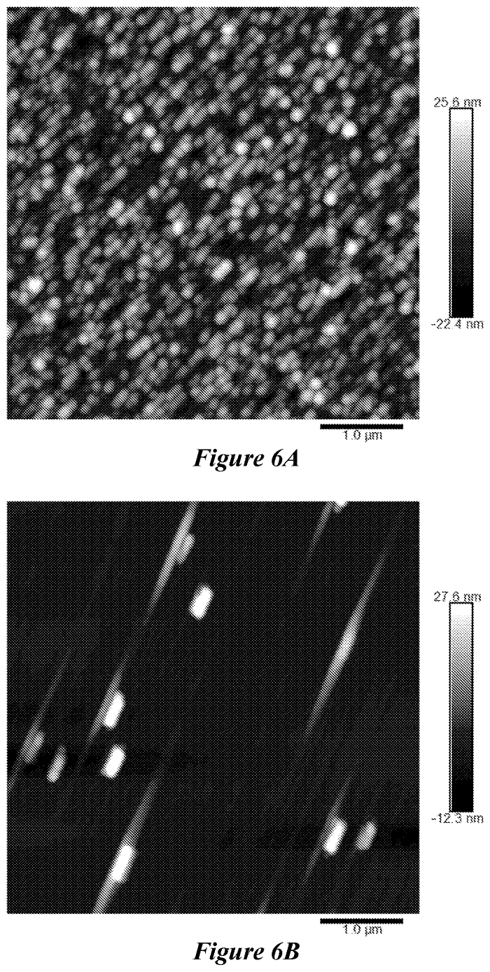

FIG. 6A-FIG. 6B shows the AFM images of LiGaO₂ samples grown at 850° C. on (010) (FIG. 6A) and (001) (FIG. 6B) Ga₂O₃ substrates. For the sample grown on (010) Ga₂O₃ substrate, the room temperature Hall measurement shows p-type doping of low-10¹⁶ cm⁻³ with hole mobility of 1-10 cm²/Vs. For the sample grown on (001) Ga₂O₃ substrate, the room temperature Hall measurement shows p-type doping of low-mid 10¹⁷ cm⁻³ with hole mobility of 1-3 cm²/Vs.

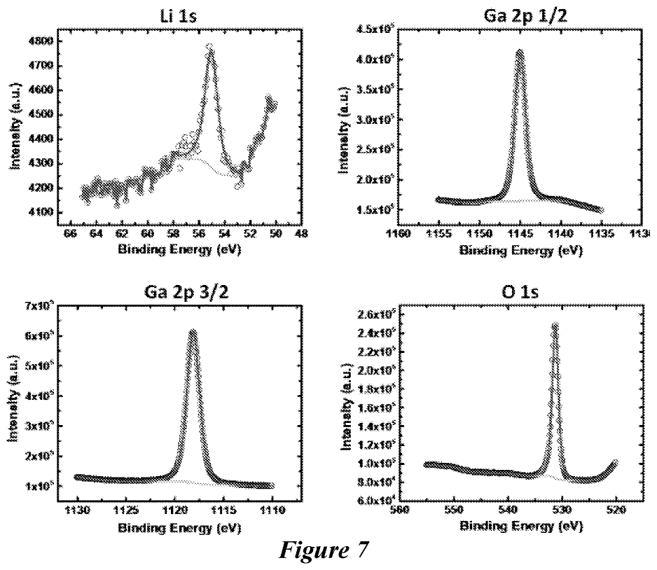

XPS measurement performed on LiGaO₂ grown on GaN-on-sapphire and sapphire substrates indicate that the Li to Ga atomic composition ratio is less than 1 (FIG. 7). This indicates that the grown LiGaO₂ films are Li poor. Depending on the growth condition and the choice of the substrate, the Li to Ga atomic ratio can vary between 0 to 1.

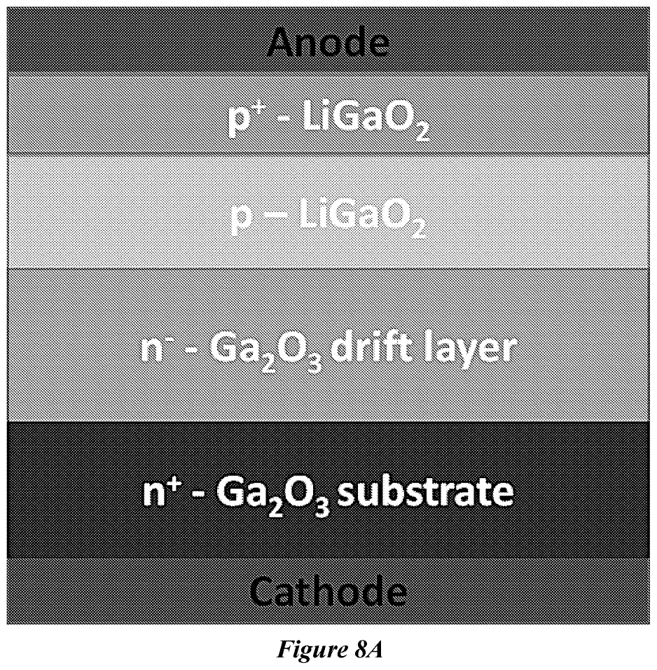

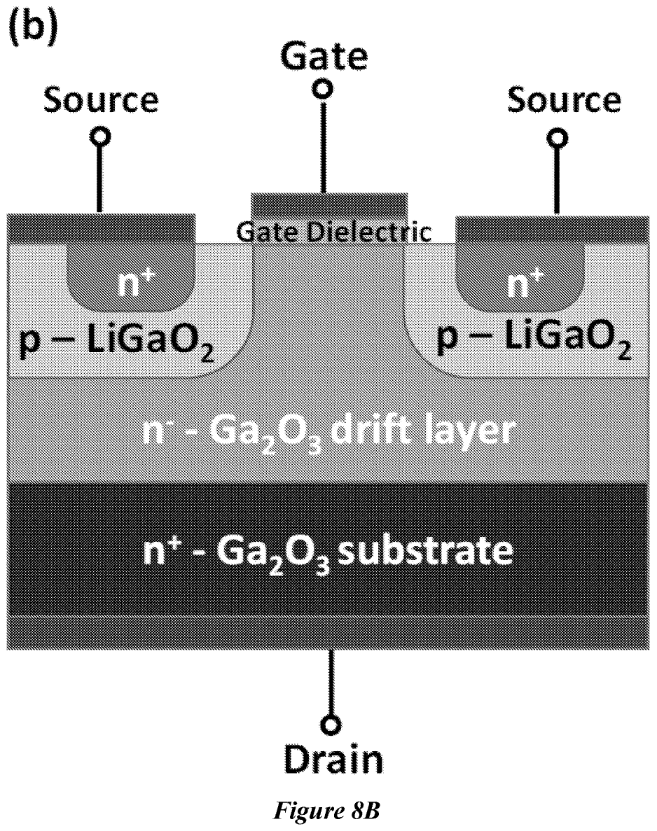

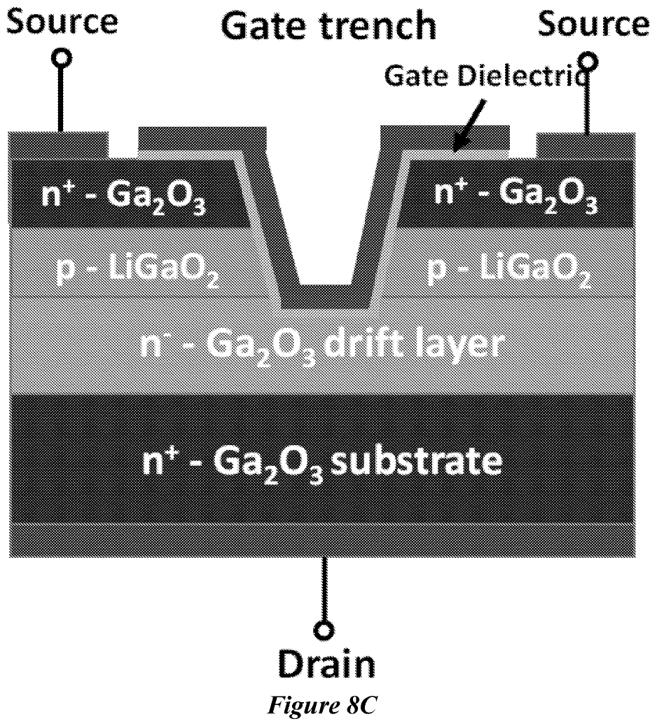

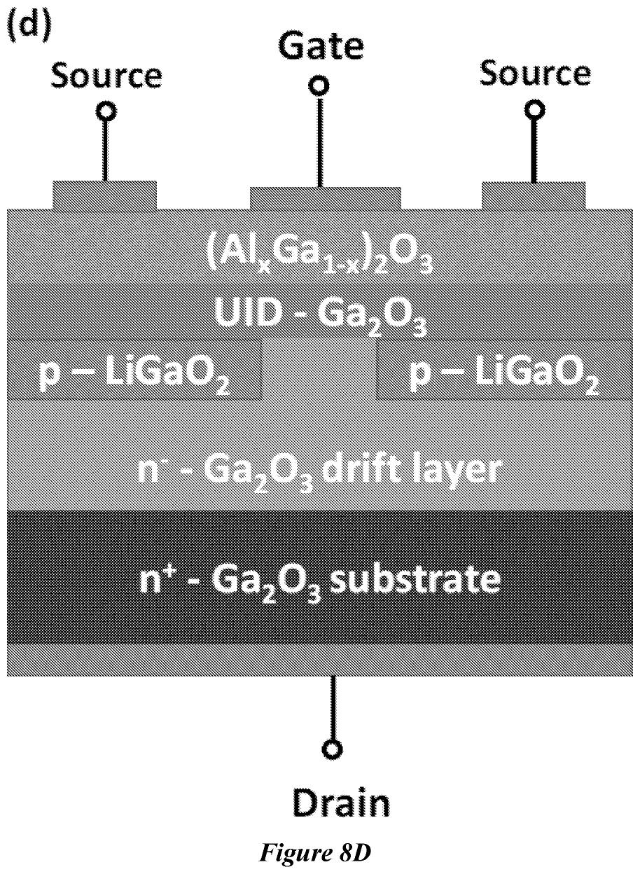

With the successful demonstration of p-type conductivity of Li poor LiGaO₂, multiple device designs are proposed for power device applications. FIG. 8A represents a vertical PN diodes based on n⁻—Ga₂O₃ drift layer, n⁺—Ga₂O₃ substrate and p-LiGaO₂ layer. FIG. 8B represents a LiGaO₂—Ga₂O₃ MOSFET. FIG. 8C represents a LiGaO₂—Ga₂O₃ trench MOSFET. FIG. 8D represents a LiGaO₂—Ga₂O₃ current aperture vertical electron transistor (CAVET). In these designs, the key structure is based on the n-Ga₂O₃/p-LiGaO₂ heterojunction.

### Example 2—Ultra-Wide Bandgap Oxide Semiconductor with P-Type Conductivity

Beta-Gallium oxide (β-Ga₂O₃) has emerged as a promising material for future power devices due to its ultrawide bandgap (~4.9 eV), high critical electric field (Ec), controllable doping, and availability of high quality, large-diameter wafers (Pearton S J et al. Appl. Phys. Rev. 2018, 5(1), 011301). While n-type β-Ga₂O₃ can be readily obtained through Si or Sn doping, the existence of p-type β-Ga₂O₃ remains undocumented. One potential approach to create β-Ga₂O₃ devices with a p-n junction involves using a heterojunction between β-Ga₂O₃ and another p-type semiconductor. An oxide material is preferred as the p-type semiconductor in this scenario, as it prevents interfacial oxidation reactions that would occur with non-oxide materials, enabling more efficient device fabrication methods. Recent developments have employed p-type nickel oxide (with a bandgap of 3.4-4 eV) to form p-n junction diodes with β-Ga₂O₃ (Kokubun Y et al. Appl. Phys. Express 2016, 9(9), 091101). Since the initial report, NiO/Ga₂O₃ p-n diodes have achieved multi-kilovolt breakdown voltage (BV) and low differential specific on-resistance (R_{ON,SP}) (Lu X et al. IEEE Electron Device Lett. 2020, 41(3), 449-452; Wang Y et al. IEEE Trans. Power Electron. 2022, 37(4), 3743-3746; Wang B et al. IEEE Electron Device Lett. 2023, 44(2), 221-224). However, the performance of these devices is significantly limited by the comparatively smaller bandgap of NiO.

Recently, there has been renewed interest in LiGaO₂ as a potential ultra-wide bandgap semiconductor material. LiGaO₂ is a transparent ceramic material that has previously been explored for its applications in piezoelectric and nonlinear optical fields (Boonchun A et al. Phys. Rev. B 2010, 81(23), 23521; Gupta S N et al. J. Appl. Phys. 1976, 47(3), 858-860; Nanamatsu S et al. Jpn. J. Appl. Phys. 1972, 11(6), 816; Knoll P et al. Phys. Rev. B 1984, 29(4), 2221-2226; Rashkeev S N et al. JOSA B 1999, 16(12), 2217-2222). It can be grown as a bulk single crystal, making it suitable as a lattice-matched substrate for GaN epitaxial growth (Ishii T et al. J. Cryst. Growth 1998, 186(3), 409-419; Marezio M. Acta Crystallogr. 1965, 18(3), 481-484; Christensen A et al. IEEE Trans. Electron Devices 2005, 52(8), 1683-1688; Doolittle W A et al. Solid-State Electron. 2000, 44(2), 229-238; Sakurada K et al. Appl. Phys. Lett. 2007, 90(21), 211913; Chen C et al. J. Cryst. Growth 2014, 402, 325-329). LiGaO₂ possesses a wurtzite-based crystal structure and can be viewed as an I-III-VI₂ analog of the II-VI material ZnO. The crystal structure features an ordered arrangement of Li and Ga atoms on the cation sublattice of the wurtzite, with the ground state represented by the Pna2₁ space group (β-LiGaO₂). Furthermore, studies have examined mixed alloy systems of ZnO and LiGaO₂, as well as ZnO/LiGaO₂ heterojunctions (Ohkubo I et al. J. Appl. Phys. 2002, 92(9), 5587-5589; Omata T et al. J. Appl. Phys. 2008, 103(8), 083706; Omata T et al. Jpn. J. Appl. Phys. 2011, 50(3R), 031102). Recent studies suggest that LiGaO₂ can be doped n-type with Si or Ge, which holds promise for ultrawide-gap semiconductor applications (Boonchun A et al. J. Appl. Phys. 2019, 126(15), 155703; Boonchun A et al. Oxide-Based Mater. Devices II, SPIE, 2011, pp. 129-134; Dabsamut K et al. J. Phys. Appl. Phys. 2020, 53(27), 274002; Lenyk C A et al. J. Appl. Phys. 2018, 124(13), 135702; Skachkov D et al. J. Phys. Appl. Phys. 2020, 53(17), 17LT01). From this perspective, LiGaO₂ may offer certain advantages compared to β-Ga₂O₃, such as its simpler tetrahedrally coordinated crystal structure and potentially even wider bandgap.

Herein, an ultra-wide bandgap semiconductor called LiₓGa_{y}O_{z} is introduced, which exhibits high p-type conductivity. The materials were obtained using a customized mist chemical vapor deposition (CVD) technique. Unintentionally doped LiₓGa_{y}O_{z} thin films can be deposited on GaN-on-sapphire templates, as well as on on-axis and offcut c-sapphire substrates using the mist-CVD chamber. To prepare the source solutions, Gallium acetylacetonate (Ga(acac)₃, [CH₃COCH═C(O—)CH₃]₃Ga, 99.99%) and lithium acetoacetate (C₄H₅LiO₃, 99.95%) are dissolved in deionized (DI) water, with a Ga/Li molar ratio of approximately 1. The solutions are used to generate atomized particles via an ultrasonic generator operating at 1.7 MHz. The atomized particles are then delivered into a growth chamber using Argon (Ar) as the carrier gas. Growth substrates are loaded in the growth chamber and the growth temperature can be tuned widely between 800-1000° C. Through a series of material characterization techniques, it was confirmed that the films grown on the respective substrates exhibited a spinel-cubic structure known as LiGa₅O₈. The p-type conductive films were found to have a composition rich in Li.

LiGa₅O₈ is a complex oxide compound that belongs to the spinel family of compounds and has an isostructural relationship with the MgAl₂O₄ spinel. Its crystal structure is characterized by a lattice constant of a=8.203 Å and space group P4_332̅. In this structure the Li⁺ ions in LiGa₅O₈ are coordinated to six equivalent O²⁻ ions, resulting in the formation of LiO₆ octahedra. These octahedra share corners with six equivalent GaO₄ tetrahedra and edges with six equivalent GaO₆ octahedra, giving rise to the overall crystalline structure of LiGa₅O₈ (Áhman J et al. Acta Chem. Scand. 1996, 50(5), 391-394).

LiGa₅O₈ has been the subject of considerable research interest due to its intriguing luminescent properties, particularly when doped with transition metals (MT) or rare earth (RE) impurities (Liu F et al. Sci. Rep. 2013, 3(1), 1554; Ao L et al. J. Eur. Ceram. Soc. 2020, 40(15), 5498-5503; Sousa Om et al. J. Solid State Chem. 2020, 289, 121472). For instance, when doped with Cr³⁺, it exhibits persistent luminescence properties and holds promise for biomedical imaging applications. The structural, electronic, and optical properties of both undoped and Cr³⁺-doped LiGa₅O₈ have been investigated via density functional theory (DFT) (Sousa Om et al. J. Solid State Chem. 2020, 289, 121472; De Sousa O M et al. Comput. Theor. Chem. 2018, 1123, 96-101). Theoretical calculations suggest a bandgap of approximately 5.7 eV, which renders LiGa₅O₈ a potential ultra-wide bandgap semiconductor. However, to date, there have been no experimental reports on thin film growth of undoped LiGa₅O₈.

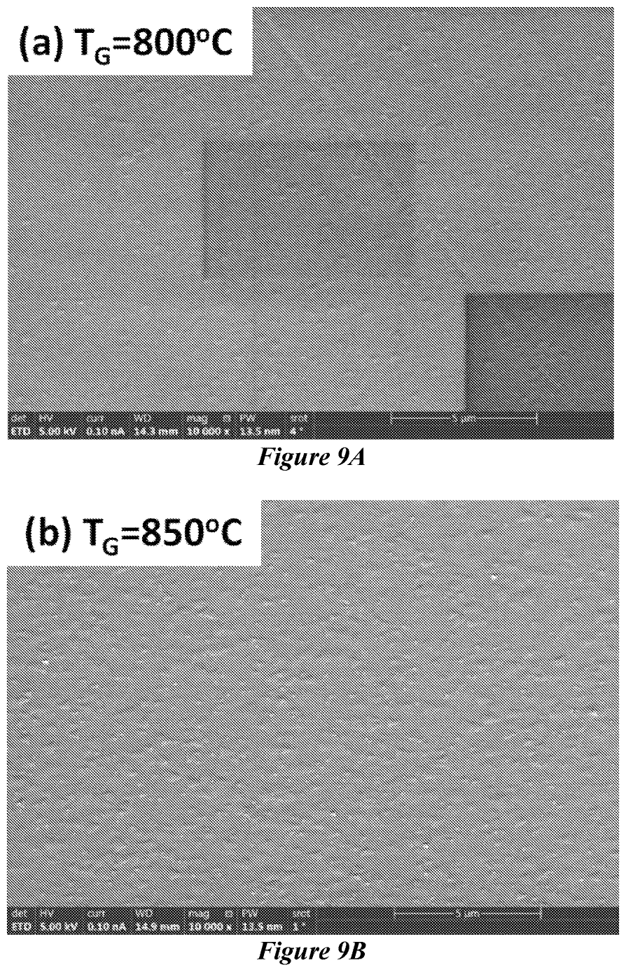

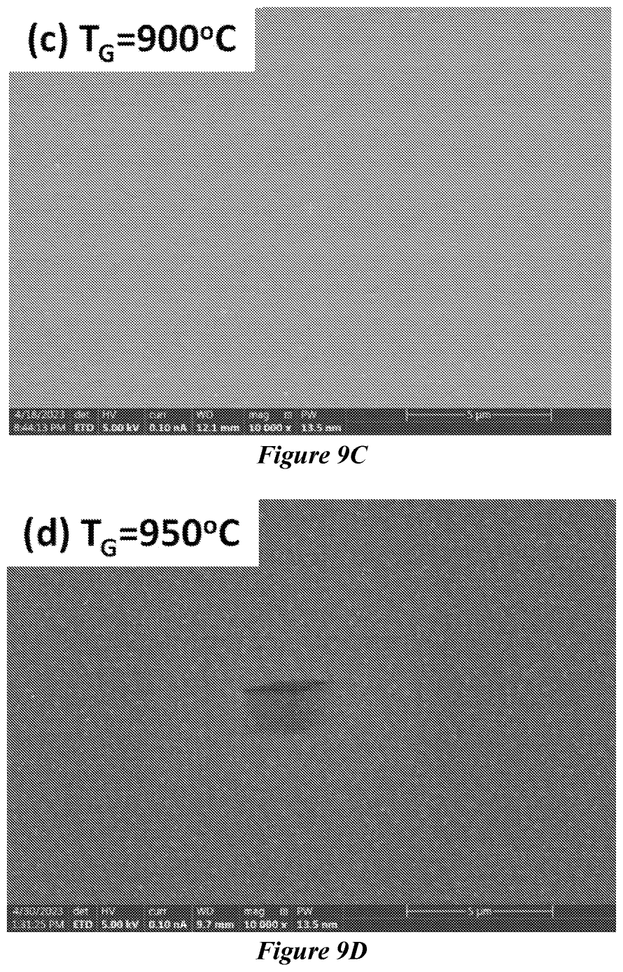

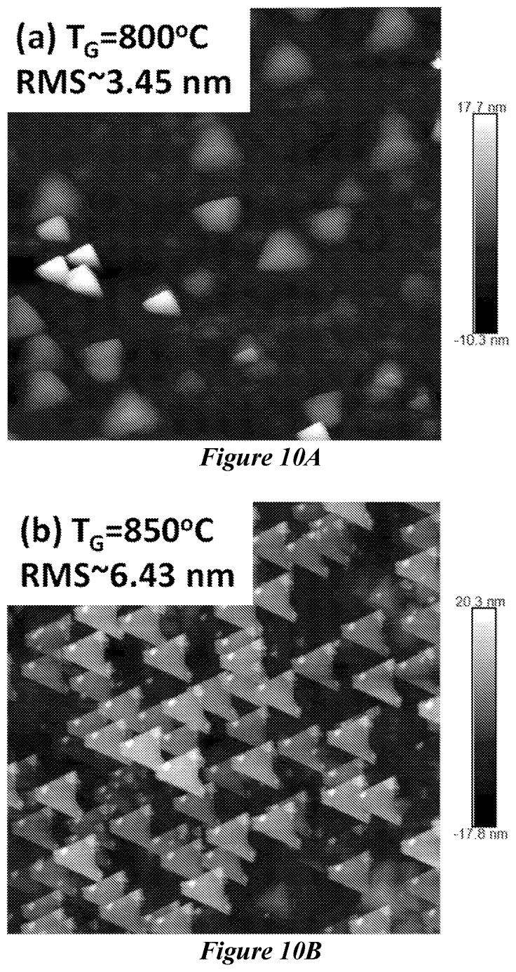

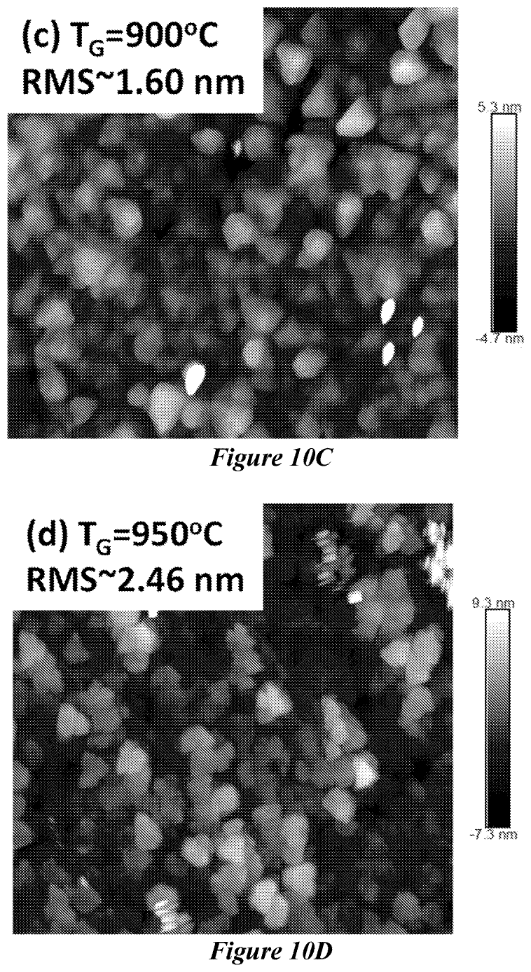

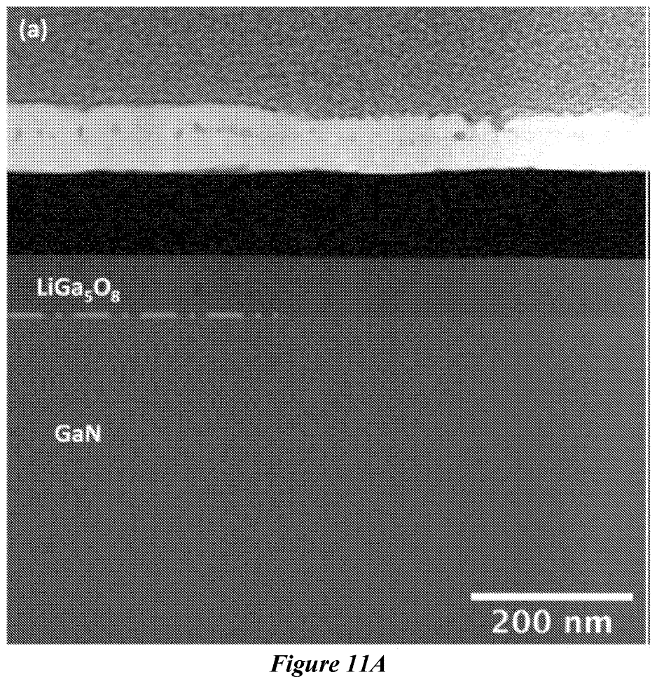

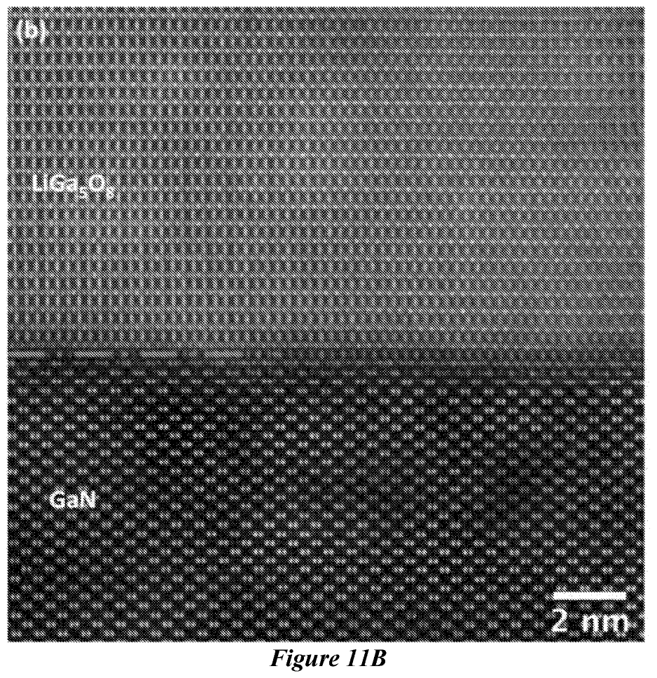

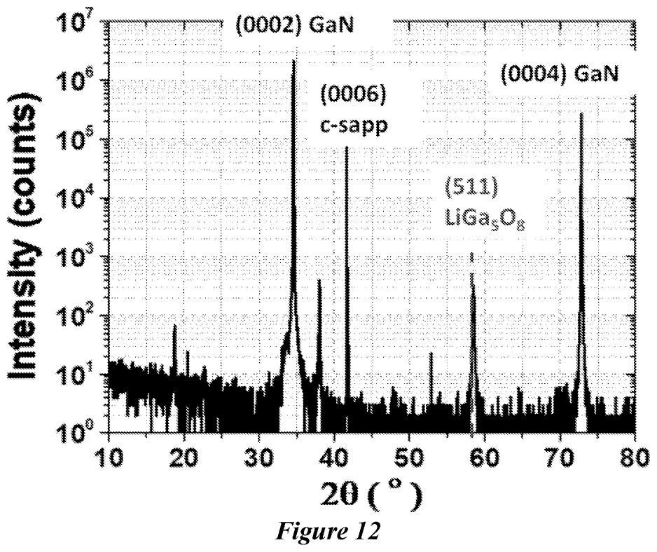

Herein, the CVD growth of Li-rich LiGa₅O₈ that exhibits p-type conductivity is demonstrated. This is an important discovery as there does not exist an ultrawide bandgap oxide semiconductor that has been demonstrated with p-type conductivity. FIG. 9A-FIG. 9D shows the surface morphology of LiGa₅O₈ samples grown on GaN on sapphire templates at different growth temperatures. It is confirmed with the corresponding AFM images as shown in FIG. 10A-FIG. 10D that at the growth temperature of 900° C., the smoothest surface is achieved. The surface roughness RMS is determined to be around 1.60 nm. The thickness of the as-grown film at 900° C. is measured by cross-sectional TEM image to be around 60 nm, as shown in FIG. 11A. A sharp interface between the grown film and GaN layer can be observed. The spinel cubic structure of the as-grown film is also shown by the atomic resolution HAADF STEM image in FIG. 11B. FIG. 12 shows the XRD spectrum of the same sample. The XRD peaks at around 34.55°, 41.68° and 72.86° are attributed to the GaN and sapphire peaks from the substrate, while possible LiGa₅O₈ (511) peaks at around 58.46° can be observed. Note that other peaks at around 18.74° and 38.01° are also noticeable, indicating the existence of possible rotated crystal domains in the as-grown film.

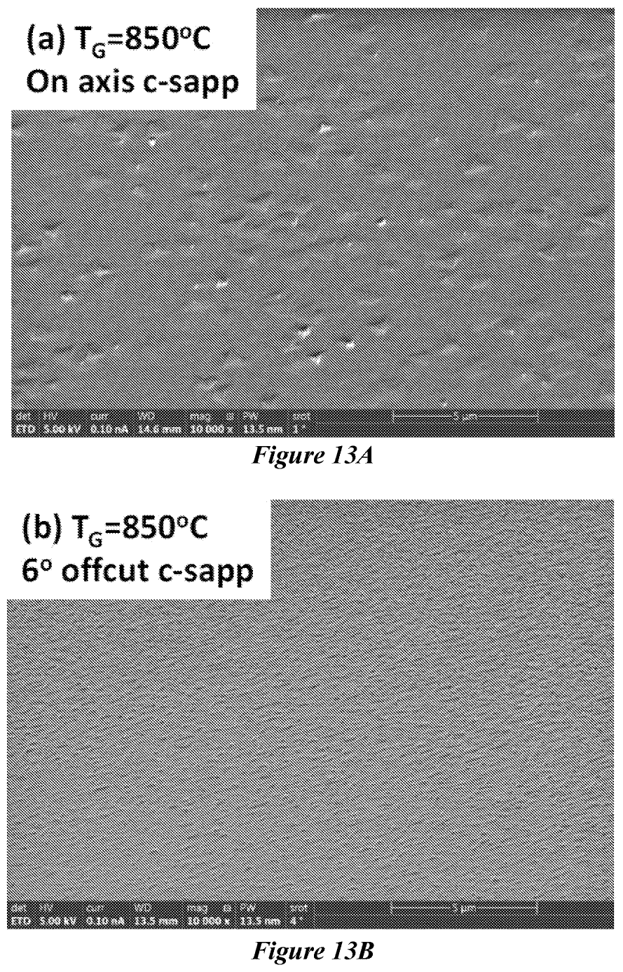

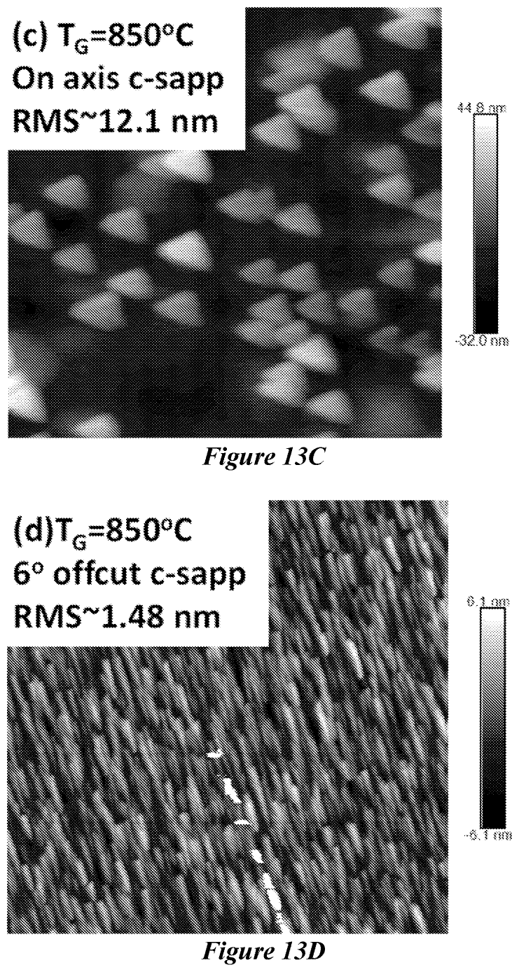

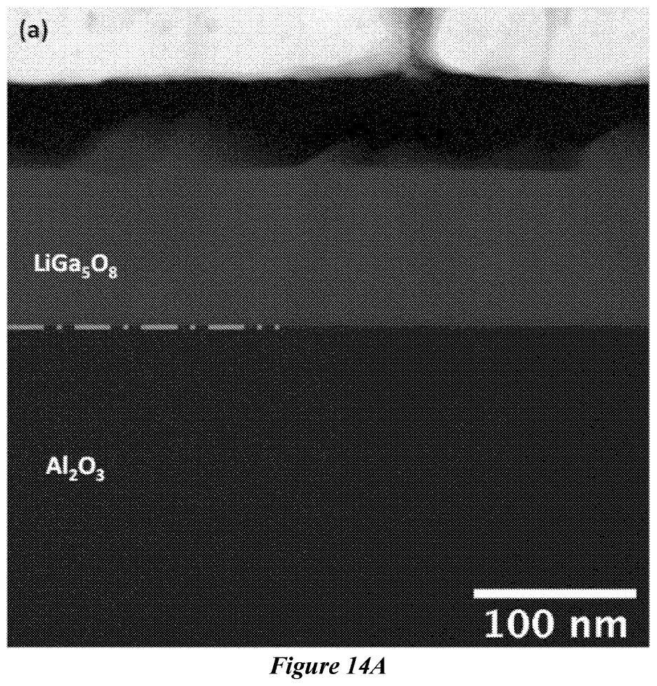

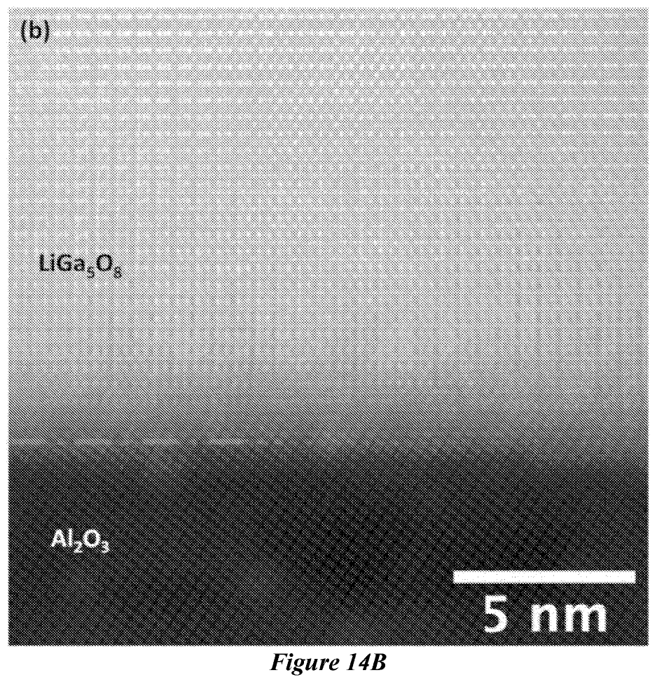

Similar surface morphology can be observed on LiGa₅O₈ samples grown on co-loaded c-sapphire substrates. FIG. 13A-FIG. 13D shows the plan-view SEM images of the LiGa₅O₈ sample grown at 850° C. on on-axis and 6°-offcut c-plane sapphire substrates as well as the corresponding AFM images. It is worth noticing that with the use of offcut angles, better surface morphology can be achieved for the films grown on sapphire substrates. Cross-sectional TEM imaging and atomic resolution HAADF STEM image of the sample grown on on-axis c-sapphire substrate, as is shown in FIG. 14A-FIG. 14B, confirm a film thickness of around 96 nm and the same spinel cubic structure as the samples grown on GaN templates. Hall measurement suggests a robust p-type conductivity for this sample, as is shown in Table 1.

TABLE 1
Hall measurement results of LiGa₅O₈ samples grown
on on-axis c-sapphire substrate at 850° C.

| Growth | | | Bulk | |
|---|---|---|---|---|
| Temper- | | Hall | concentration | Mobility |
| ature | substrate | current | (cm⁻³) | (cm²/V · s) |
| 850° C. | On axis | 10 μA | 4.6E+17 | 1.88 |
| | c-sapphire | 1 μA | 2.4E+18 | 0.349 |

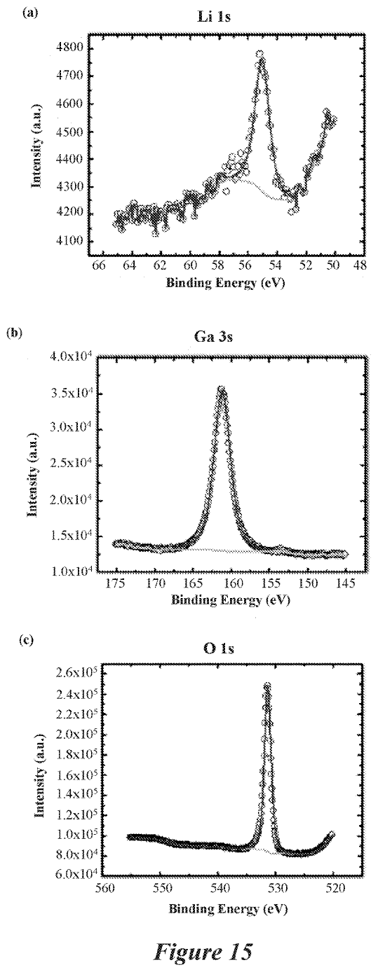

The atomic compositions of the as-grown films were examined using X-ray photoemission spectroscopy (XPS). The acquired Li 1s, Ga 3s and O 1s peaks from LiGa₅O₈ film grown on GaN on sapphire template at 900° C. are shown in FIG. 15 as an example. The curves are fitted with a Voigt peak shape and a Shirley background is assumed. The atomic ratio of Li/Ga, Li/O and Ga/O are then derived using the fitting peak areas. As is shown in Table 2, the samples grown on all three substrates show a ratio of ~1:5:8 for Li/Ga/O with Li being compositional rich. Additionally, the rutherford backscattering spectroscopy (RBS) and nuclear reaction analysis (NRA) measurements on the sample grown on on-axis c-sapphire substrate at 900° C. also confirm its composition being rich in Li. The contents of Li, Ga, and O were determined to be approximately 9.5%, 33%, and 57.5%, respectively.

TABLE 2
Li/Ga, Li/O, and Ga/O ratio estimated from
XPS measurement results using the peak
areas of Li 1 s, Ga 3 s, and O 1 s peaks for LiGa₅O₈
samples grown with different conditions.

| Growth | | Li/Ga | Li/O | Ga/O |
|---|---|---|---|---|
| Temperature | substrate | ratio | ratio | ratio |
| 850° C. | On axis c-sapphire | 0.21 | 0.15 | 0.70 |
| | 6° offcut c-sapphire | 0.24 | 0.16 | 0.67 |
| | GaN on sapphire template | 0.22 | 0.15 | 0.67 |
| 900° C. | GaN on sapphire template | 0.26 | 0.18 | 0.69 |

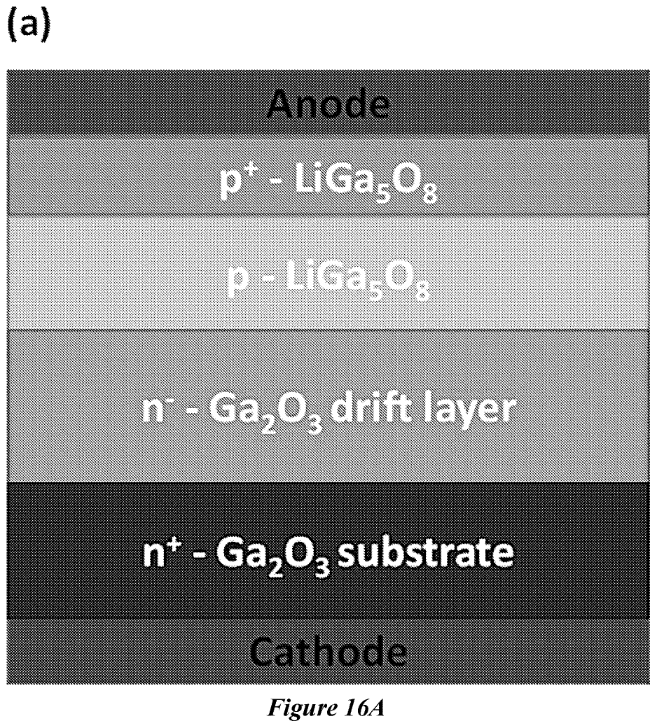

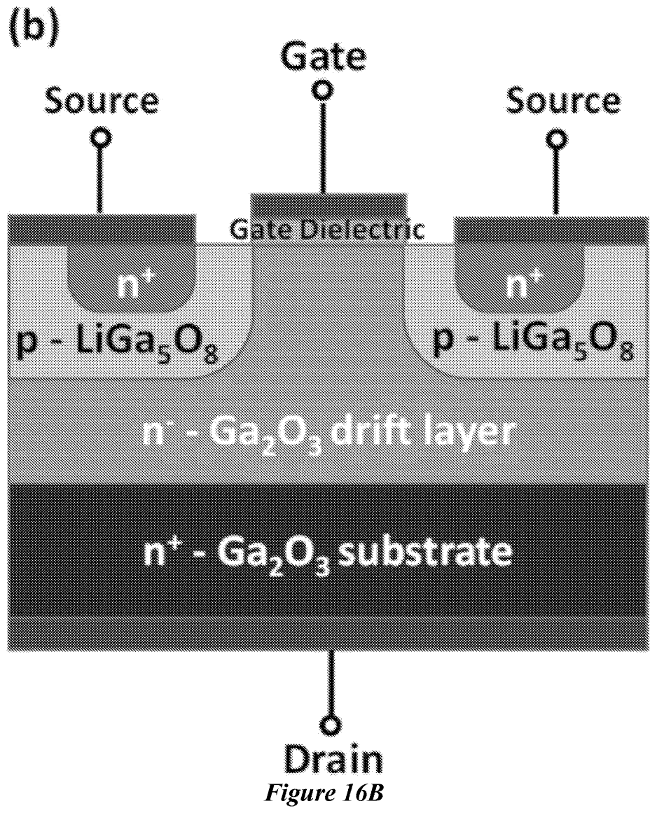

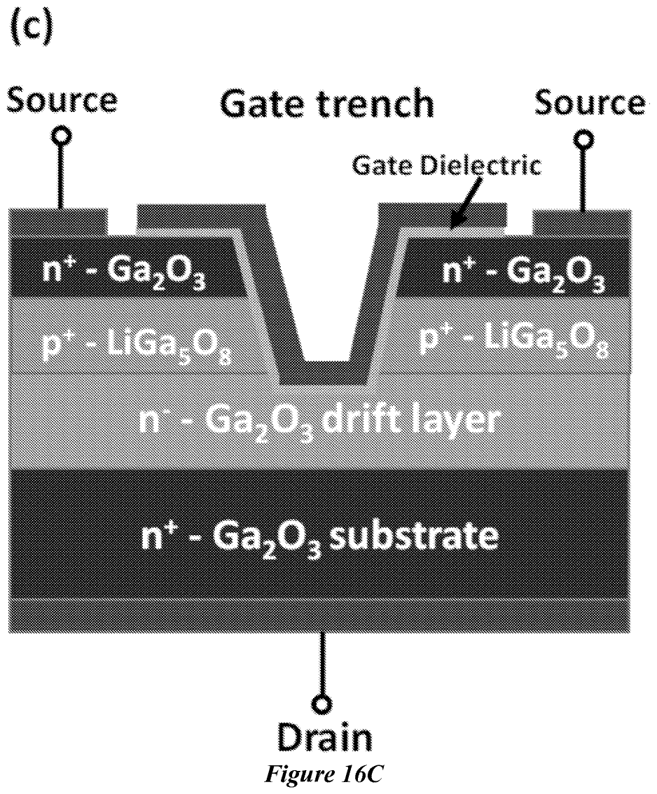

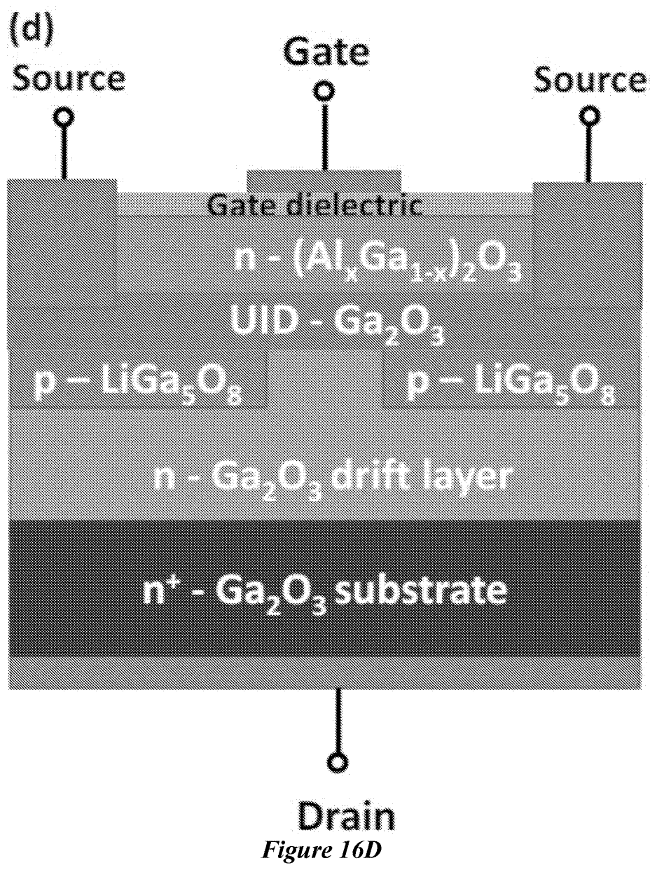

With the successful demonstration of p-type conductivity of Li rich LiGa₅O₈, multiple device designs are proposed for power device applications. FIG. 16A represents a vertical PN diodes based on n⁻—Ga₂O₃ drift layer, n⁺—Ga₂O₃ substrate and p-LiGa₅O₈ layer. FIG. 16B represents a LiGa₅O₈—Ga₂O₃ MOSFET. FIG. 16C represents a LiGa₅O₈—Ga₂O₃ trench MOSFET. FIG. 16D represents a LiGa₅O₈—Ga₂O₃ current aperture vertical electron transistor (CAVET). In these designs, the key structure is based on the n-Ga₂O₃/p-LiGa₅O₈ heterojunctions.

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A composition comprising ultrawide bandgap oxide semiconductor with p-type conductivity comprising MₐGa_{b}O_{c} where M is Li or Na.

Example 2: The composition of any examples herein, particularly example 1, wherein the composition comprises MₐGa_{b}O_{c} where M is Li or Na, a is from 0 to 1, b is from 0 to 5, and c is from 2 to 8, with the proviso that at least one of a or b is not 0.

Example 3: The composition of any examples herein, particularly example 2, wherein a is from 0 to 1 and b is from 0 to 1.

Example 4: The composition of any examples herein, particularly example 2, wherein a is from 0 to 1 and b is from 4 to 5.

Example 5: The composition of any examples herein, particularly examples 2-4, wherein a is from 0 to 1 and c is 2.

Example 6: The composition of any examples herein, particularly examples 2-4, wherein a is from 0 to 1 and c is 8.

Example 7: The composition of any examples herein, particularly examples 2-6, wherein b is from 0 to 1 and c is 2.

Example 8: The composition of any examples herein, particularly examples 2-6, wherein b is from 4 to 5 and c is 8.

Example 9: The composition of any examples herein, particularly examples 1-8, wherein the composition comprises MₐGa_{b}O₈ where M is Li or Na, a is from 0 to 1, b is from 4 to 5.

Example 10: The composition of any examples herein, particularly examples 1-8, wherein the composition comprises MₐGa_{b}O₂ where M is Li or Na, a is from 0 to 1, b is from 0 to 1, with the proviso that at least one of a or b is not 0.

Example 11: The composition of any examples herein, particularly examples 1-10, wherein the composition comprises LiₓGa₁₋ₓO₂ or NaₓGa₁₋ₓO₂ wherein x is from 0 to 1, such as from 0 to 0.5.

Example 12: The composition of any examples herein, particularly examples 1-11, wherein the composition comprises LiₓGa₁₋ₓO₂, wherein x is from 0 to 1, such as from 0 to 0.5.

Example 13: The composition of any examples herein, particularly examples 1-12, wherein Li and Ga have an atomic ratio of from 0 to 1.

Example 14: The composition of any examples herein, particularly examples 1-13, wherein the composition comprises β-LiₓGa₁₋ₓO₂.

Example 15: The composition of any examples herein, particularly examples 1-14, wherein the composition further comprises a dopant, such as a p-type dopant.

Example 16: The composition of any examples herein, particularly example 15, wherein the dopant has a concentration of from 1×10¹⁵ per cubic centimeter to 1×10²¹ cm⁻³, from 1×10¹⁵ per cubic centimeter to 1×10¹⁹ cm⁻³, or from 1×10¹⁶ to 5×10¹⁷ cm⁻³.

Example 17: The composition of any examples herein, particularly examples 1-16, wherein the composition has a mobility, such as a hole mobility, of from 0.1 to 100 cm²/Vs, such as from 1 to 10 cm²/Vs (e.g., from 2 to 5 cm²/Vs).

Example 18: A device comprising the composition of any examples herein, particularly examples 1-17.

Example 19: The device of any examples herein, particularly example 18, wherein the device further comprises a substrate, wherein the composition is deposited on the substrate as a layer.

Example 20: The device of any examples herein, particularly example 19, wherein the substrate comprises LiGaO₂, GaN on c-plane sapphire templates, on-axis c-sapphire, off-axis c-sapphire, Ga₂O₃, Si, or a combination thereof.

Example 21: The device of any examples herein, particularly examples 19-20, wherein the layer has a surface roughness with an RMS value of 15 nm or less, 10 nm or less, 5 nm or less, or 2.5 nm or less.

Example 22: The device of any examples herein, particularly examples 19-21, wherein the layer has an average thickness of from 100 to 1000 nm.

Example 23: The device of any examples herein, particularly examples 19-22, wherein the layer has an average thickness of from 100 to 200 nm.

Example 24: The device of any examples herein, particularly examples 19-22, wherein the layer has an average thickness of from 500 nm to 1000 nm, such as from 700 to 800 nm.

Example 25: The device of any examples herein, particularly examples 18-24, wherein the device comprises a vertical PN diode, a MOSFET device such as a power MOSFET or a trench MOSFET, a MESFET device, a MODFET device, a Current Aperture Vertical Electron Transistor (CAVET) device, or a combination thereof.

Example 26: The device of any examples herein, particularly examples 18-25, wherein the device comprises a vertical power device.

Example 27: The device of any examples herein, particularly examples 18-26, wherein the device comprises an optical device, an electronic device, an optoelectronic device, or a combination thereof.

Example 28: The device of any examples herein, particularly examples 18-27, wherein the device comprises a diode.

Example 29: The device of any examples herein, particularly examples 18-28, wherein the device comprises a n-Ga₂O₃/p-MₐGa_{b}O_{c}, n-AlN/p-MₐGa_{b}O_{c}, n-BN/p-MₐGa_{b}O_{c}, n-GaN/p-MₐGa_{b}O_{c}, or n-AlGaN/p-MₐGa_{b}O_{c} heterojunction.

Example 30: The device of any examples herein, particularly examples 18-29, wherein the device comprises a n-Ga₂O₃/p-LiₐGa_{b}O_{c}, n-AlN/p-LiₐGa_{b}O_{c}, n-BN/p-LiₐGa_{b}O_{c}, n-GaN/p-LiₐGa_{b}O_{c}, or n-AlGaN/p-LiₐGa_{b}O_{c} heterojunction.

Example 31: The device of any examples herein, particularly examples 18-30, wherein the device comprises a n-Ga₂O₃/p-LiₐGa_{b}O₂, n-AlN/p-LiₐGa_{b}O₂, n-BN/p-LiₐGa_{b}O₂, n-GaN/p-LiₐGa_{b}O₂, or n-AlGaN/p-LiₐGa_{b}O₂ heterojunction.

Example 32: The device of any examples herein, particularly examples 18-31, wherein the device comprises a n-Ga₂O₃/p-LiₓGa₁₋ₓO₂, n-AlN/p-LiₓGa₁₋ₓO₂, n-BN/p-LiₓGa₁₋ₓO₂, n-GaN/p-LiₓGa₁₋ₓO₂, or n-AlGaN/p-LiₓGa₁₋ₓO₂ heterojunction.

Example 33: The device of any examples herein, particularly examples 18-32, wherein the device comprises a n-Ga₂O₃/p-LiₓGa₁₋ₓO₂ heterojunction.

Example 34: The device of any examples herein, particularly examples 18-30, wherein the device comprises a n-Ga₂O₃/p-LiₐGa_{b}O₈, n-AlN/p-LiₐGa_{b}O₈, n-BN/p-LiₐGa_{b}O₈, n-GaN/p-LiₐGa_{b}O₈, or n-AlGaN/p-LiₐGa_{b}O₈ heterojunction.

Example 35: The device of any examples herein, particularly example 34, wherein the device comprises a n-Ga₂O₃/p-LiGa₅O₈ heterojunction.

Example 36: A method of use of the composition of any examples herein, particularly examples 1-17.

Example 37: A method of making the composition of any examples herein, particularly examples 1-17, the method comprising contacting a gallium containing precursor and a lithium or sodium containing precursor at a temperature in the presence of oxygen or an oxygen containing precursor to thereby react the gallium containing precursor, the lithium or sodium containing precursor, and the oxygen or the oxygen containing precursor to form the composition.

Example 38: The method of any examples herein, particularly example 37, the method comprising contacting the gallium containing precursor and the lithium containing precursor at a temperature in the presence of oxygen or an oxygen containing precursor to thereby react the gallium containing precursor, the lithium containing precursor, and the oxygen or the oxygen containing precursor to form the composition.

Example 39: The method of any examples herein, particularly example 37 or example 38, wherein the gallium containing precursor comprises Ga(acac)₃ ([CH₃COCH═C(O—)CH₃]₃Ga), trimethylgallium (TMGa), triethyl gallium (TEGa), or a combination thereof.

Example 40: The method of any examples herein, particularly examples 37-39, wherein the gallium containing precursor comprises Ga(acac)₃ ([CH₃COCH═C(O—)CH₃]₃Ga).

Example 41: The method of any examples herein, particularly examples 37-40, wherein the sodium containing precursor comprises sodium acetoacetate (C₄H₅NaO₃), sodium tert-butoxide (NaO^{t}Bu), sodium hexamethyldisilazide (NaHMDS), 2,2,6,6-tetramethyl-3,5-heptanedionato sodium (NaTMHD), or a combination thereof.

Example 42: The method of any examples herein, particularly examples 37-41, wherein the lithium containing precursor comprises lithium acetoacetate (C₄H₅LiO₃), lithium tert-butoxide (LiO^{t}Bu), lithium hexamethyldisilazide (LiHMDS), 2,2,6,6-tetramethyl-3,5-heptanedionato lithium (LiTMHD), or a combination thereof.

Example 43: The method of any examples herein, particularly examples 37-42, wherein the lithium containing precursor comprises lithium acetoacetate (C₄H₅LiO₃).

Example 44: The method of any examples herein, particularly examples 37-43, wherein the gallium containing precursor and/or the lithium or sodium containing precursor independently comprise(s) a fluid.

Example 45: The method of any examples herein, particularly examples 37-44, wherein the gallium containing precursor and/or the lithium or sodium containing precursor are independently provided with a carrier gas.

Example 46: The method of any examples herein, particularly example 45, wherein the carrier gas comprises argon, helium, N₂, and the like, or combinations thereof.

Example 47: The method of any examples herein, particularly example 45 or example 46, wherein the carrier gas comprises argon.

Example 48: The method of any examples herein, particularly examples 37-47, wherein the temperature is 600° C. to 1100° C., from 600° C. to 1000° C., from 800° C. to 1000° C., or from 800° C. to 950° C.

Example 49: The method of any examples herein, particularly examples 37-48, wherein the method comprises metal organic chemical vapor deposition (MOCVD), molecular-beam epitaxy (MBE), hydride vapor phase epitaxy (HVPE), pulsed laser deposition (PLD), low pressure chemical vapor deposition (LPCVD), mist-CVD, or a combination thereof.

Example 50: The method of any examples herein, particularly examples 37-49, wherein the method comprises mist-CVD.

Example 51: The method of any examples herein, particularly examples 37-50, wherein the method comprises depositing the composition on a substrate.

Example 52: The method of any examples herein, particularly example 51, wherein the substrate comprises LiGaO₂, GaN on c-plane sapphire templates, on-axis c-sapphire, off-axis c-sapphire, Ga₂O₃, Si, or a combination thereof.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A composition comprising ultrawide bandgap oxide semiconductor with p-type conductivity comprising: 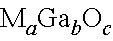
where
M is Li or Na,
a is from 0 to 1,
b is from 0 to 5, and
c is from 2 to 8,
with the proviso that at least one of a or b is not 0.

2. (canceled)

3. The composition of claim 1, wherein a is from 0 to 1 and b is from 0 to 1.

4. The composition of claim 1, wherein a is from 0 to 1 and b is from 4 to 5.

5. The composition of claim 1, wherein a is from 0 to 1 and c is 2.

6. The composition of claim 1, wherein a is from 0 to 1 and c is 8.

7. The composition of claim 1, wherein b is from 0 to 1 and c is 2.

8. The composition of claim 1, wherein b is from 4 to 5 and c is 8.

9. The composition of claim 1, wherein the composition comprises MₐGa_{b}O₈ where M is Li or Na, a is from 0 to 1, b is from 4 to 5.

10. The composition of claim 1, wherein the composition comprises MₐGa_{b}O₂ where M is Li or Na, a is from 0 to 1, b is from 0 to 1, with the proviso that at least one of a or b is not 0.

11. The composition of claim 1, wherein the composition comprises LiₓGa₁₋ₓO₂ or NaₓGa₁₋ₓO₂ wherein x is from 0 to 1.

12. The composition of claim 1, wherein the composition comprises LiₓGa₁₋ₓO₂, wherein x is from 0 to 1.

13. The composition of claim 1, wherein Li and Ga have an atomic ratio of from 0 to 1.

14. The composition of claim 12, wherein the composition comprises β-LiₓGa₁₋ₓO₂.

15. The composition of claim 1, wherein the composition further comprises a dopant.

16. The composition of claim 15, wherein the dopant has a concentration of from 1×10¹⁵ per cubic centimeter to 1×10²¹ cm⁻³.

17. The composition of claim 1, wherein the composition has a hole mobility of from 0.1 to 100 cm²/Vs.

18. A device comprising the composition of claim 1, wherein the device comprises a n-Ga₂O₃/p-MₐGa_{b}O_{c}, n-AlN/p-MₐGa_{b}O_{c}, n-BN/p-MₐGa_{b}O_{c}, n-GaN/p-MₐGa_{b}O_{c}, or n-AlGaN/p-MₐGa_{b}O_{c} heterojunction.

19.-35. (canceled)

36. A method of use of the composition of claim 1.

37. A method of making the composition of claim 1, the method comprising contacting a gallium containing precursor and a lithium or sodium containing precursor at a temperature in the presence of oxygen or an oxygen containing precursor to thereby react the gallium containing precursor, the lithium or sodium containing precursor, and the oxygen or the oxygen containing precursor to form the composition.

38.-52. (canceled)

53. The composition of claim 15, wherein the dopant is a p-type dopant.
